(19) United States
(12) Patent Application Publication
(10) Pub. No.: US 2026/0280580 A1
(43) Pub. Date: Sep. 17, 2026

(54) HYBRID SWITCHING SCHEME FOR A CAPACITOR DIGITAL-TO-ANALOG CIRCUIT IN A SUCCESSIVE APPROXIMATION REGISTER ANALOG-TO-DIGITAL CONVERTER

(71) Applicant: QUALCOMM Incorporated, San Diego, CA (US)

(72) Inventors: Chienchung YANG, San Diego, CA (US); Xiaopeng ZHONG, Seattle, WA (US); Ramkumar SIVAKUMAR, San Diego, CA (US); Lei SUN, San Diego, CA (US)

(21) Appl. No.: 19/077,448

(22) Filed: Mar. 12, 2025

(51) Int. Cl. H03M 1/46

(52) U.S. Cl. CPC H03M 1/46

(57) ABSTRACT

An analog-to-digital converter includes first switches configured to selectively couple the first terminal of a first capacitor in a first capacitive digital-to-analog converter (DAC) to one of three voltages, second switches configured to switch the first terminal of a second capacitor in the first capacitive DAC between two of the three voltages, third switches configured to selectively couple the first terminal of a first capacitor in a second capacitive DAC to one of the three voltages, and fourth switches configured to switch the first terminal of a second capacitor in the second capacitive DAC between two of the three voltages. The first and third switches may be controlled based on values of respective ternary numbers. The second and fourth switches may be controlled based on values of respective binary numbers.

### TECHNICAL FIELD

Aspects of the present disclosure relate generally to analog-to-digital conversion, and more particularly, to analog-to-digital converters (ADCs).

### BACKGROUND

An analog-to-digital converter (ADC) is used to convert an analog signal into a digital signal. One type of ADC is the successive approximation register (SAR) ADC, which converts an analog input signal into a digital signal using successive digital approximation. SAR ADCs have become popular for implementing low-power ADCs in advanced technologies.

### SUMMARY

Certain aspects of the disclosure relate to systems, apparatus, methods and techniques for analog-to-digital conversion. In one aspect, analog-to-digital converter (ADC) includes a pair of digital-to-analog converters (DACs) that are operated using a hybrid switching scheme, whereby different switching configurations are used for resolving the least significant bit (LSB) and non-LSB bits. The analog-to-digital converter further includes a successive approximation register (SAR).

In various aspects of the disclosure, an ADC includes a first capacitor in a first capacitive DAC, and first switches configured to selectively couple the first terminal of the first capacitor in the first capacitive DAC to one of three voltages. The ADC also includes a second capacitor in the first capacitive DAC and second switches configured to switch the first terminal of the second capacitor in the first capacitive DAC between two of the three voltages. The ADC also includes a first capacitor in a second capacitive DAC and third switches configured to selectively couple the first terminal of the first capacitor in the second capacitive DAC to one of the three voltages. The ADC also includes a second capacitor in the second capacitive DAC and fourth switches configured to switch the first terminal of the second capacitor in the second capacitive DAC between two of the three voltages. The first switches and the third switches may be controlled based on value of a ternary number, and the second switches and the fourth switches may be controlled based on value of a first single-digit binary number.

In various aspects of the disclosure, an apparatus includes means for coupling a first terminal of a first capacitor in a first capacitive DAC to one of three voltages based on a value of a first ternary number. The apparatus further includes means for coupling a first terminal of a second capacitor in the first capacitive DAC to one of the three voltages selected by a value of a first single-digit binary number. The apparatus further includes means for coupling a first terminal of a first capacitor in a second capacitive DAC to one of the three voltages based on a value of a second ternary number. The apparatus further includes means for coupling a first terminal of a second capacitor in the second capacitive DAC to one of the three voltages selected by a value of a second single-digit binary number.

In various aspects of the disclosure, a method for performing analog-to-digital conversion includes coupling a first terminal of a first capacitor in a first capacitive DAC to one of three voltages based on value of a first ternary number, coupling a first terminal of a second capacitor in the first capacitive DAC to one of two voltages based on value of a first single-digit binary number, coupling a first terminal of a first capacitor in a second capacitive DAC to one of the three voltages based on value of a second ternary number, and coupling a first terminal of a second capacitor in the second capacitive DAC to one of two voltages based on value of a second single-digit binary number.

In certain aspects, the three voltages include a reference voltage. The reference voltage may be coupled to each capacitor in each capacitive DAC when an input to the analog-to-digital converter is being sampled.

In certain aspects, the first capacitor in the first capacitive DAC provides a capacitance that is larger than the capacitance provided by the second capacitor in the first capacitive DAC by factor of 2ⁿ where n is a non-negative integer. The first capacitor in the first capacitive DAC may be one of a plurality of capacitors in the first capacitive DAC that provide different binary-weighted capacitances. The first capacitor in the first capacitive DAC may provide a capacitance that is nominally the same as the capacitance provided by the first capacitor in the second capacitive DAC. The first capacitor in the second capacitive DAC may be one of a plurality of capacitors in the second capacitive DAC that provide different binary-weighted capacitances.

In certain aspects, the ADC includes a comparator configured to generate a code representative of a voltage difference between outputs of the first capacitive DAC and the second capacitive DAC. The calibration signal may be generated by a logic circuit configured to receive a density code based on a sequence of codes generated by the comparator. A second terminal of the first capacitor in the first capacitive DAC and a second terminal of the second capacitor in the first capacitive DAC are coupled to a first input of the comparator. A second terminal of the first capacitor in the second capacitive DAC and a second terminal of the second capacitor in the second capacitive DAC may be coupled to a second input of the comparator.

### BRIEF DESCRIPTION OF THE DRAWINGS

FIG. 1 shows examples of systems that include an analog-to-digital converter (ADC) according to certain aspects of the present disclosure.

FIG. 2 shows a block diagram that illustrates an example of a successive approximation register (SAR) ADC that may be adapted according to certain aspects of the present disclosure.

FIG. 3 illustrates a system that includes one or more SAR ADCs and a class-D amplifier that is used to drive a pair of loudspeakers.

FIG. 4 illustrates certain aspects of the operation of a successive approximation register (SAR) ADC.

FIG. 5 illustrates an example of a SAR ADC that may adapted or configured in accordance with certain aspects of this disclosure.

FIG. 6 illustrates a sampling phase configuration of the SAR ADC illustrated in FIG. 5.

FIGS. 7-9 illustrate examples of conversion phase configurations of the SAR ADC illustrated in FIG. 5.

FIG. 10 illustrates a first example of common mode voltage in a differential SAR ADC.

FIG. 11 illustrates an example of asymmetric capacitance switching in a differential SAR ADC.

FIG. 12 illustrates a second example of common mode voltage in a differential SAR ADC.

FIG. 13 illustrates a first example of SAR ADC that can implement a hybrid capacitance switching scheme in accordance with certain aspects of this disclosure.

FIG. 14 illustrates a sampling phase configuration of the SAR ADC illustrated in FIG. 13.

FIGS. 15-18 illustrate examples of conversion phase configurations of the SAR ADC illustrated in FIG. 13.

FIG. 19 illustrates a second example of SAR ADC that can implement a hybrid capacitance switching scheme in accordance with certain aspects of this disclosure.

FIG. 20 illustrates a common mode voltage in a SAR ADC that implements a hybrid capacitance switching scheme in accordance with certain aspects of this disclosure.

FIG. 21 is a flow diagram illustrating an example of a method for performing analog-to-digital conversion in accordance with certain aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well-known structures and components are shown in block diagram form in order to avoid obscuring such concepts.

With reference now to the Figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

The terms “computing device” and “mobile device” are used interchangeably herein to refer to any one or all of servers, personal computers, smartphones, cellular telephones, tablet computers, laptop computers, netbooks, ultrabooks, palm-top computers, personal data assistants (PDAs), wireless electronic mail receivers, multimedia Internet-enabled cellular telephones, Global Positioning System (GPS) receivers, wireless gaming controllers, and similar personal electronic devices which include a programmable processor. While the various aspects are particularly useful in mobile devices (e.g., smartphones, laptop computers, etc.), which have limited resources (e.g., processing power, battery, size, etc.), the aspects are generally useful in any computing device that may benefit from improved processor performance and reduced energy consumption.

The term “multicore processor” is used herein to refer to a single integrated circuit (IC) chip or chip package that contains two or more independent processing units or cores (e.g., CPU cores, etc.) configured to read and execute program instructions. The term “multiprocessor” is used herein to refer to a system or device that includes two or more processing units configured to read and execute program instructions.

The term “system on chip” (SoC) is used herein to refer to a single integrated circuit (IC) chip that contains multiple resources and/or processors integrated on a single substrate. A single SoC may contain circuitry for digital, analog, mixed-signal, and radio-frequency functions. A single SoC may also include any number of general purpose and/or specialized processors (digital signal processors (DSPs), modem processors, video processors, etc.), memory blocks (e.g., read only memory (ROM), random access memory (RAM), flash, etc.), and resources (e.g., timers, voltage regulators, oscillators, etc.), any or all of which may be included in one or more cores.

Memory technologies described herein may be suitable for storing instructions, programs, control signals, and/or data for use in or by a computer or other digital electronic device. Any references to terminology and/or technical details related to an individual type of memory, interface, standard, or memory technology are for illustrative purposes only, and not intended to limit the scope of the claims to a particular memory system or technology unless specifically recited in the claim language. Mobile computing device architectures have grown in complexity, and now commonly include multiple processor cores, SoCs, co-processors, functional modules including dedicated processors (e.g., communication modem chips, GPS receivers, etc.), complex memory systems, intricate electrical interconnections (e.g., buses and/or fabrics), and numerous other resources that execute complex and power intensive software applications (e.g., video streaming applications, etc.).

Process technology employed to manufacture semiconductor devices, including IC devices is continually improving. Process technology includes the manufacturing methods used to make IC devices and defines transistor size, operating voltages and switching speeds. Features that are constituent elements of circuits in an IC device may be referred as technology nodes and/or process nodes. The terms technology node, process node, process technology may be used to characterize a specific semiconductor manufacturing process and corresponding design rules. Faster and more power-efficient technology nodes are being continuously developed through the use of smaller feature size to produce smaller transistors that enable the manufacture of higher-density ICs.

Certain aspects of the disclosure are applicable to circuits that generate, transmit, receive, process and/or propagate differential signals. A wire pair may comprise two wires, connectors, interconnects or other conductors over which a differential signal is transmitted. The differential signal may be carried in two phase versions over the wire pair, whereby the wires, connectors, interconnects or other conductors in the wire pair carry versions of the differential signal that are phase-shifted from each other by 180°. The versions of the differential signal transmitted over the wire pair may be referred to as complementary signals. The differential signal is transmitted over wires, connectors, interconnects or other conductors using voltages of equal voltage magnitude and opposite polarity. A signal that represents the difference between the signaling state of the wire pair can be generated. An identical direct current (DC) offset from system ground carried by each wire of the pair may be referred to as a common-mode voltage. The common-mode voltage may be measured at the input of a device that receives a differential signal. An identical signal carried in-phase by each wire of the pair may be referred to as a common-mode signal.

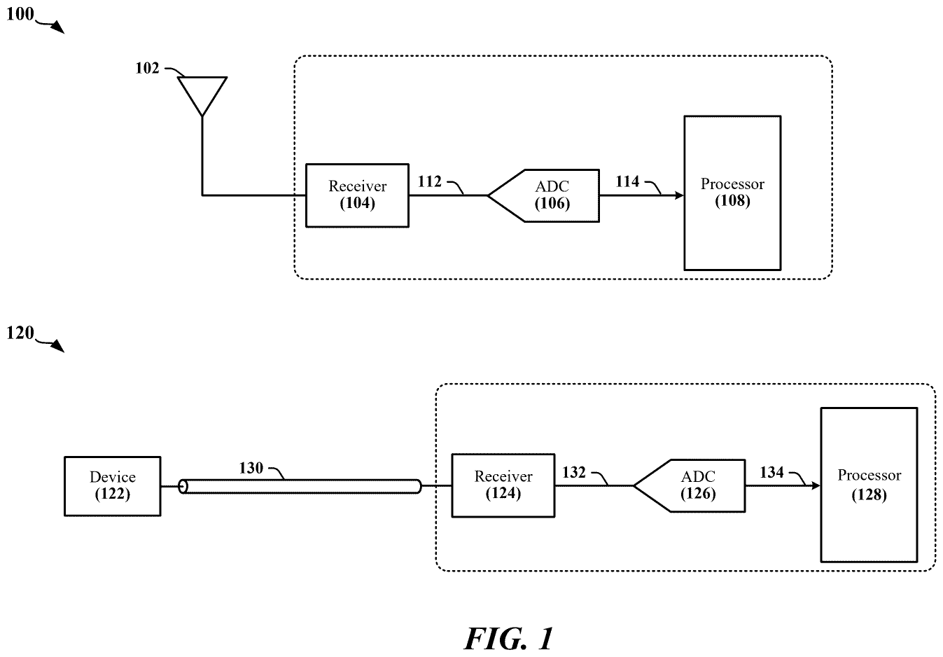

Certain aspects of this disclosure relate to certain types of analog-to-digital converter (ADC). An ADC may be used in a system to convert an analog signal into a digital signal. FIG. 1 shows an example of a system 100 in which an ADC 106 may be used according to certain aspects. In this example, the ADC 106 is configured to convert an analog signal 112 received at an input of the ADC 106 into a digital signal 114 that is provided at an output of the ADC 106. The analog signal 112 is provided by a receiver 104 that is coupled to the ADC 106. The system 100 also includes a processor 108 that is coupled to the output of the ADC 106 and that is configured to receive the digital signal 114. In this example, the system 100 may be part of a wireless communication device (e.g., a handset).

The receiver 104 may be coupled to one or more antennas 102, and may be configured to receive a radio frequency (RF) signal via the one or more antennas 102. For example, the RF signal may be transmitted from a base station, an access point, or another wireless communication device. The receiver 104 may be configured to process the received RF signal into an analog baseband signal, and output the analog baseband signal to the ADC 106 for conversion into a digital signal. Processing performed by the receiver 104 may include frequency down-conversion, filtering, amplification, etc. The ADC 106 converts the analog baseband signal into a digital signal, and outputs the digital signal to the processor 108. The processor 108 may process the digital signal to recover data from the digital signal and process the recovered data. Processing performed by the processor 108 may include demodulation, decoding, etc. The processor 108 may include a processor core, a digital signal processor (DSP), an application specific integrated circuit (ASIC), a field programmable gate array (FPGA) or other programmable logic device, or any combination thereof.

FIG. 1 also shows another example of a system 120 in which an ADC 126 may be used according to certain aspects. In this example, the ADC 126 is configured to convert an analog signal 132 received at an input of the ADC 126 into a digital signal 134 that is output by the ADC 126. The analog signal 132 is provided by a receiver 124 that is coupled to the ADC 126. The system 120 also includes a processor 128 that is coupled to the ADC 126 and configured to receive the digital signal 134.

In this example, the receiver 124 may be coupled to a wired channel 130, and may be configured to receive an analog signal via the wired channel 130. The wired channel 130 (also referred to as a wired link) may include one or more metal traces, one or more metal wires, a cable, an optical fiber, or any combination thereof. In this example, the wired channel 130 may be used to provide communication between a device 122 and the processor 128, in which a transmit driver (not shown) in the device 122 transmits the analog signal to the receiver 124 over the wired channel 130. The device 122 may include a peripheral device, a sensor device, or another type of device.

In the illustrated system 120, the receiver 124 may process the analog signal from the wired channel 130 into a processed analog signal, and output the processed analog signal to the ADC 126 for digital conversion. Processing performed by the receiver 124 may include filtering, amplification, equalization, etc. The ADC 126 converts the processed analog signal into a digital signal, and outputs the digital signal to the processor 128. The processor 128 may then process the digital signal to recover data from the digital signal and process the recovered data. The processor 128 may include a processor core, a digital signal processor (DSP), an application specific integrated circuit (ASIC), a field programmable gate array (FPGA) or other programmable logic device, or any combination thereof.

Thus, the systems 100, 120 illustrated in FIG. 1 show examples of systems in which ADCs according to aspects of the present disclosure may be used. However, it is to be appreciated that ADCs according to aspects of the present disclosure may also be used in other types of systems to convert an analog signal into a digital signal.

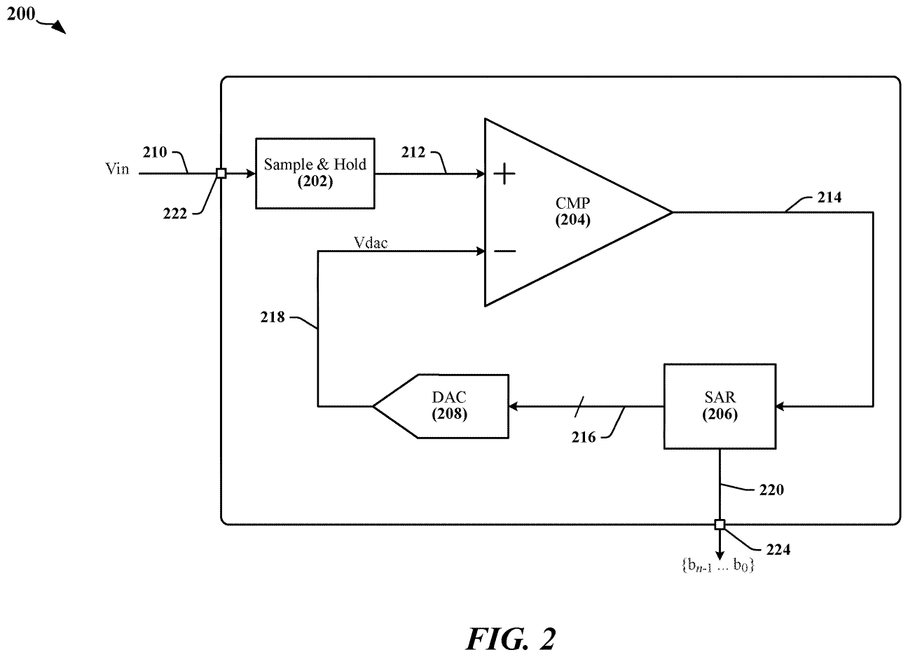

The ADC 106 in system 100 and the ADC 126 in system 120 may each be implemented with a successive approximation register (SAR) ADC. In this regard, FIG. 2 shows a simplified block diagram of an example of a SAR ADC 200 according to aspects of the present disclosure. The exemplary SAR ADC 200 is intended to illustrate the general concept of the use of successive approximate in analog-to-digital conversion known in the art. It is to be appreciated that the present disclosure is not limited to the exemplary SAR ADC 200 shown in FIG. 2.

The SAR ADC 200 is configured to receive an analog input voltage 210 (labeled “Vin”) at an input 222, convert the input voltage 210 into a digital signal 220, and output the digital signal 220 at an output 224. The digital signal 220 includes bits (e.g., a sequence of bits) providing a digital representation of the input voltage 210.

The SAR ADC 200 includes a sample and hold circuit 202, a comparator 204, a SAR 206 (also referred to as SAR logic or another term), and a digital-to-analog converter (the DAC 208). The sample and hold circuit 202 has an input that is coupled to the input 222 of the SAR ADC 200 and an output 212 that is coupled to a first input of the comparator 204. The sample and hold circuit 202 is configured to sample the input voltage 210 at the input 222 of the SAR ADC 200, and hold the sampled input voltage Vin at the first input of the comparator 204.

The SAR 206 has an input that is configured to receive a difference signal 214 generated by the comparator 204, a first output coupled to the output 224 of the SAR ADC 200, and a second output coupled to an input of the DAC 208. The DAC 208 has an output that is coupled to a second input of the comparator 204. The DAC 208 may be an n-bit DAC configured to receive an n-bit digital signal 216 from the SAR 206, convert the n-bit digital signal 216 into a DAC voltage (the Vdac voltage 218), and output the Vdac voltage 218 to the second input of the comparator 204. The Vdac voltage 218 may be calculated as follows:

$$V dac = {b}_{n - 1} \cdot \frac{{V}_{ref}}{2} + {b}_{n - 2} \cdot \frac{{V}_{ref}}{4} + {b}_{n - 3} \cdot \frac{{V}_{ref}}{8} + … + {b}_{0} \cdot \frac{{V}_{ref}}{{2}^{n}} \qquad ( 1 )$$

where V_{ref} is a reference voltage, and bₙ₋₁ to b₀ are the n bits of the digital signal 216 output by the SAR 206. In this example, bₙ₋₁ is the most significant bit (MSB) and b₀ is the least significant bit (LSB). It is to be appreciated that the Vdac voltage 218 is not limited to the example given in equation (1).

The comparator 204 is configured to compare the sampled input voltage Vin with the Vdac voltage 218, and output the difference signal 214. The logic value (i.e., logic state) of the difference signal 214 indicates whether the sampled representation of the input voltage 210 is greater than or less than the Vdac voltage 218. In one example, the difference signal 214 is one (i.e., logic one) if the sampled representation of the input voltage 210 is greater than the Vdac voltage 218, and the difference signal 214 is zero (i.e., logic zero) if the sampled representation of the input voltage 210 is less than the Vdac voltage 218. The SAR 206 is configured to convert the sampled representation of the input voltage 210 into a digital value at the output 224 using the comparator 204 and the DAC 208, as discussed further below. In some implementations, a logic one may correspond to a voltage approximately equal to a supply voltage, and a logic zero may correspond to a voltage approximately equal to zero volts.

The SAR ADC 200 is configured to convert the input voltage 210 into a digital signal in an analog-to-digital conversion operation that includes a sampling phase and a conversion phase. During the sampling phase, the sample and hold circuit 202 samples the input voltage 210 at the input 222 of the SAR ADC 200. During the conversion phase, the sample and hold circuit 202 holds the sampled representation of the input voltage 210 at the first input of the comparator 204.

During the conversion phase, the SAR 206 converts the sampled representation of the input voltage 210 into a digital signal 220 at the output 224 using the comparator 204 and the DAC 208. To do this, the SAR 206 may output a digital signal 216 to the DAC 208, and sequentially resolve (i.e., determine) the bits bₙ₋₁ to b₀ of the digital signal 220 based on the difference signal 214 provided by the comparator 204 and utilizing a binary search, as discussed in the following.

The SAR 206 starts the binary search with the MSB bₙ₋₁. The SAR 206 resolves the MSB bₙ₋₁ during a first conversion cycle. To resolve the MSB bₙ₋₁, the SAR 206 sets the MSB bₙ₋₁ to one and the remaining bits bₙ₋₂ to b₀ to zero. This causes the DAC 208 to output a voltage of ½Vref to the second input of the comparator 204 (i.e., Vdac=½Vref). The SAR 206 then resolves the MSB bₙ₋₁ based on the output of the comparator 204. If the difference signal 214 is one (i.e., the sampled input voltage Vin is greater than ½Vref), then the SAR 206 resolves the MSB bₙ₋₁ to a bit value of one. If the difference signal 214 is zero (i.e., the sampled input voltage Vin is less than ½Vref), then the SAR 206 resolves the MSB bₙ₋₁ to a bit value of zero.

After resolving the MSB bₙ₋₁, the SAR 206 resolves the second most significant bit bₙ₋₂ during a second conversion cycle. To resolve bit bₙ₋₂, the SAR 206 sets the MSB bₙ₋₁ to its resolved bit value, sets bit bₙ₋₂ to one, and sets the remaining bits bₙ₋₃ to b\hat{ } to zero. This causes the DAC 208 to output a voltage of ¼Vref to the second input of the comparator 204 (i.e., Vdac=¼Vref) if the resolved bit value of the MSB bₙ₋₁ is zero, and output a voltage of ¾Vref if the resolved bit value of the MSB bₙ₋₁ is one. The SAR 206 then resolves (i.e., determines) bit bₙ₋₂ based on the output of the comparator 204. If the difference signal 214 is one, then the SAR 206 resolves bit bₙ₋₂ to a bit value of one. If the difference signal 214 is zero, then the SAR 206 resolves bit bₙ₋₂ to a bit value of zero.

The SAR 206 may repeat the above process for each of the remaining bits bₙ₋₃ to b₀ to resolve the remaining bits bₙ₋₃ to b₀. In this example, the SAR 206 resolves all n bits bₙ₋₁ to b₀ over n conversion cycles. After all n bits bₙ₋₁ to b₀ have been resolved, the SAR 206 may output the result (also referred to as a digital code) in the digital signal 220 at the output 224 of the SAR ADC 200. The digital code may include the resolved bits bₙ₋₁ to b₀.

The SAR ADC 200 may perform the analog-to-digital conversion discussed above periodically to track the input voltage Vin over time. For example, the sample and hold circuit 202 may receive a sampling clock signal. In this example, during each cycle (i.e., period) of the sampling clock signal, the sample and hold circuit 202 samples the input voltage Vin and the SAR ADC 200 converts the sampled input voltage Vin into an n-bit digital signal (i.e., digital code). Thus, in this example, the SAR ADC 200 may perform the analog-to-digital conversion discussed above for each cycle of the sampling clock signal. The sampling clock signal may have a frequency, for example, anywhere in the range of tens of kilohertz to over a gigahertz. However, it is to be appreciated that the SAR ADC 200 is not limited to this example. The SAR ADC 200 may be deployed for use in a variety of portable and battery-powered instruments. In other examples, the SAR ADC 200 may be deployed within devices, ICs or other circuits that are used to drive loudspeakers or other audio transducers, in biomedical devices and/or is certain automotive applications.

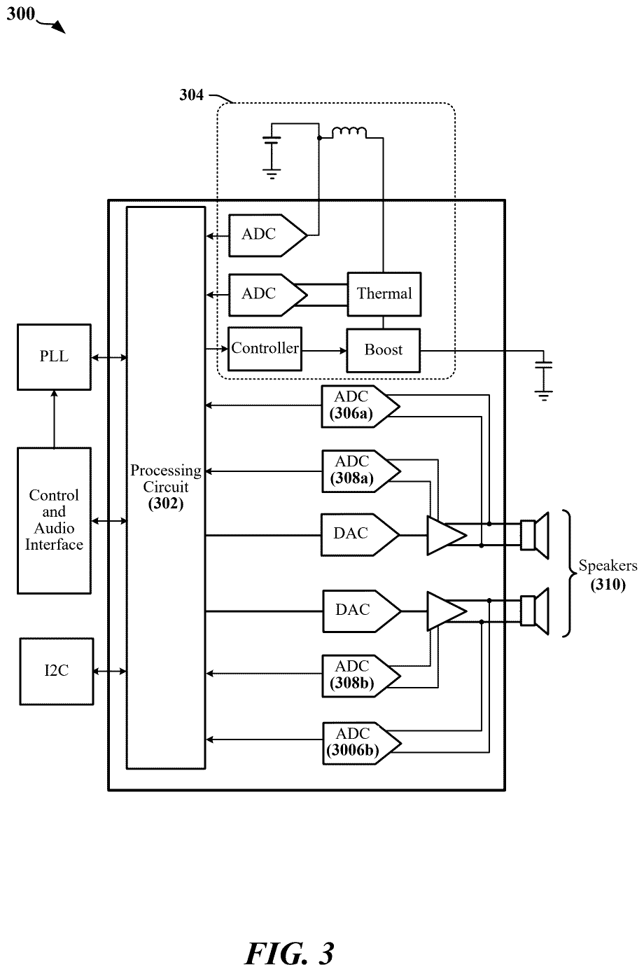

FIG. 3 illustrates a system 300 that includes a class-D amplifier, which may be used to drive a pair of loudspeakers 310. A class-D amplifier operates as a switching amplifier whereby a processing circuit 302 or another controller generates a switching signal that switches between voltage rails at a switching frequency. The switching signal is modulated by a lower-frequency audio signal. In one example, the switching signal is pulse-width modulated (PWM) to obtain a PWM signal. An amplified audio signal can be obtained by using a low-pass filter to block the switching frequency component in the PWM signal.

The illustrated system 300 includes multiple SAR ADCs 306a, 306b, 308a, 308b to monitor load applied to the loudspeakers 310. One pair of SAR ADCs 306a, 306b may be used to sense the voltage applied across the loudspeakers 310 and a second pair of SAR ADCs 308a, 308b may be used to sense current flows associated with the audio output. In some implementations, voltage and current for each of the loudspeakers may processed by multiplexing access to a single SAR ADC. In these implementations, a multiplexer may be used to sequence the analog signals corresponding to current and voltage information for each of the loudspeakers 310. This multiplexed configuration can reduce power consumption and the physical area of semiconductor die needed to handle the analog-to-digital conversion requirements for load monitoring.

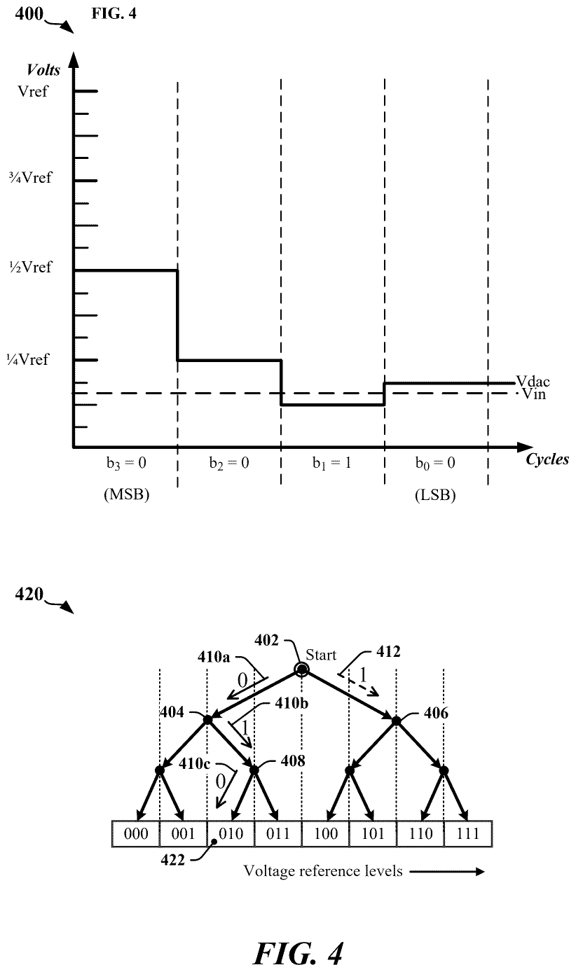

FIG. 4 includes a graph 400 that shows an example of the DAC output voltage Vdac over n conversion cycles for an exemplary input voltage Vin. For ease of illustration, the digital signal has four bits (i.e., n=4) in this example where bit b₃ is the MSB and bit b₀ is the LSB. However, it is to be appreciated that the digital signal may have a larger number of bits (i.e., n>4). As shown in FIG. 2, the SAR ADC 200 resolves one bit of the digital signal during each conversion cycle starting with the MSB and ending with the LSB. At the end of the conversion cycles, the DAC output voltage Vdac is close to the input voltage Vin.

FIG. 4 also shows a decision tree diagram 420 that illustrates an example of a binary search that may be used to resolve the bits (b₂ to b₀) of a 3-bit digital signal. The illustrated example may be implemented by the SAR ADC 200 illustrated in FIG. 2, whereby the output of the comparator 204 indicates a decision obtained by comparing the output 212 of the sample and hold circuit 202 with the Vdac voltage 218 output by the DAC 208. The Vdac voltage 218 may be adjusted based on the decision value. For example, the Vdac voltage 218 may be increased incrementally when the output 212 of the sample and hold circuit 202 is greater than the Vdac voltage 218, and decreased incrementally when the output 212 of the sample and hold circuit 202 is less than the Vdac voltage 218.

The decision tree diagram 420 corresponds to a search in which a sampled analog input is compared to a selectable or configurable voltage reference level such as the Vdac voltage 218. In the illustrated example, the search commences with the voltage reference level being set to a median or midrange voltage level 402, corresponding to the digital code ‘0b100’. For the purposes of this example, the decision is indicated as binary ‘1’ when the sampled analog input is greater than the current voltage reference level and as binary ‘0’ when the sampled analog input is less than the current voltage reference level. When the sampled analog input is less than the current voltage reference level, a first path 410a is followed that includes reducing the voltage reference level to a level 404 that is half the current voltage reference level and performing another comparison of the sampled analog input with the reduced voltage reference level. When the sampled analog input is greater than the current voltage reference level, a second path 412 is followed that includes increasing the voltage reference level to a level 406 that is 50% higher than the current voltage reference level and performing another comparison of the sampled analog input with the increased voltage reference level.

In the illustrated example, the first path 410a, 410b, 410c is followed, the voltage reference level being set to a level 404 that corresponds to the digital code ‘0b010’ and a decision is obtained that indicates that the sampled analog input is greater than the decreased voltage reference level (i.e., level 404). In the first path 410a followed based on the latter decision, the voltage reference level is set to a level 408 that corresponds to the digital code ‘0b011’ and a decision is obtained that indicates that the sampled analog input is less than the incremented voltage reference level (i.e., level 408). The illustrated binary search produces a resolved digital voltage level 422 for the sampled analog input that corresponds to the digital code ‘0b010’.

The DAC 208 in the SAR ADC 200 illustrated in FIG. 2 may be implemented using one or more capacitive DACs that have been adapted or configured in accordance with certain aspects of this disclosure. In such implementations, the sample function and/or hold function of the sample and hold circuit 202 may be integrated into the capacitive DAC. Also, the capacitive DAC may be configured to provide one or more threshold voltages for input-adaptive analog-to-digital conversion, as discussed further below.

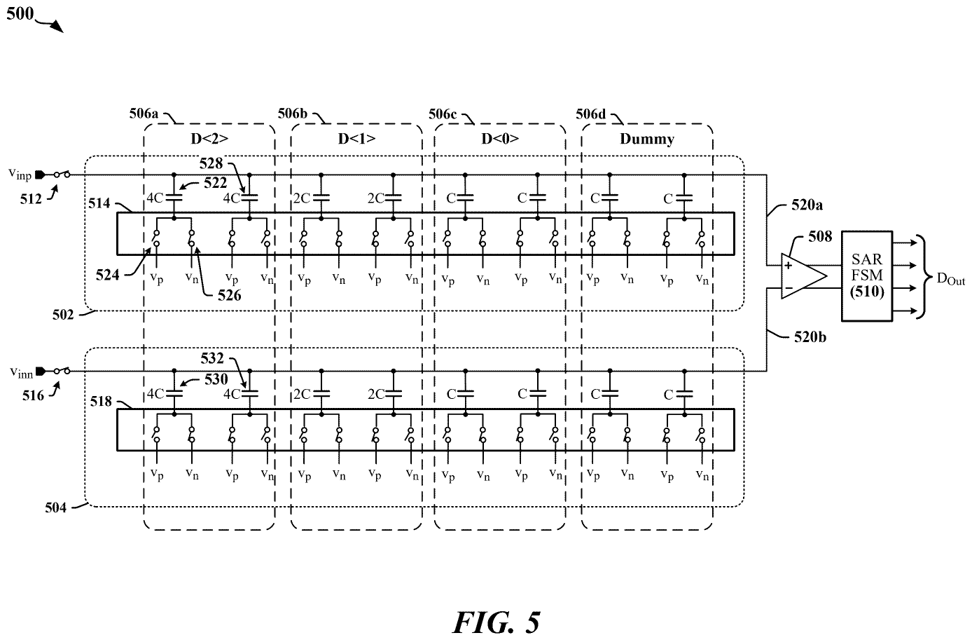

FIG. 5 illustrates an example of a differential SAR ADC 500 that is implemented using capacitive DACs. The illustrated SAR ADC 500 includes a first capacitive DAC 502, a second capacitive DAC 504, a comparator 508, a SAR 510, a first input switch 512, and a second input switch 516. A first switching circuit 514 may be operated to selectively couple capacitors in the first capacitive DAC 502 to a positive voltage (vₚ) or a negative voltage (vₙ). A second switching circuit 518 may be operated to selectively couple capacitors in the second capacitive DAC 504 to the positive voltage (vₚ) or the negative voltage (vₙ). The SAR 510 may include or cooperate with a finite state machine (FSM), a processor, sequencing logic and/or other logic circuits that can configure the first input switch 512, the second input switch 516, the first switching circuit 514 and the second switching circuit 518 based on a current state of operation of the differential SAR ADC 500.

Each of the capacitive DACs 502, 504 includes three binary-weighted bit segments 506a, 506b, 506c and a dummy bit segment 506d. Switched capacitances are configured to define weights provided by the binary-weighted bit segments 506a, 506b, 506c and by the dummy bit segment 506d. The binary weight provided by each of the bit segments 506a, 506b, 506c may be defined by magnitude of capacitance. For the purposes of this description, switched capacitances may include capacitors that each have a first plate and a second plate that can be coupled to external circuits through a first terminal and a second terminal, respectively. In some implementations, the switched capacitances may provide capacitance using some combination of capacitors, transistors, diodes and/or sources of parasitic capacitance.

In the illustrated example, the least significant bit (LSB) bit segment 506c may be assigned a binary weight of 1 and includes two capacitors that each provide a smallest capacitance, which may be referred to as the unit capacitance. The next bit segment 506b may be assigned a binary weight of 2 and includes two capacitors that each provide a capacitance that is that is two times greater than the unit capacitance. The most significant bit (MSB) bit segment 506a may be assigned a binary weight of 4 and includes two capacitors that each provide a capacitance that is four times greater than the unit capacitance.

In the illustrated SAR ADC 500, the first capacitive DAC 502 includes a first switching circuit 514 that includes switches that are coupled to the first terminal of the capacitors in the first capacitive DAC 502. The second capacitive DAC 504 includes a second switching circuit 518 that includes switches that are coupled to the first terminal of the capacitors in the second capacitive DAC 504. Switches in the switching circuits 514, 518 enable the first terminal of each capacitor to be selectively coupled to the positive voltage (vₚ) or a negative voltage (vₙ). For example, a first capacitor 522 in the MSB bit segment 506a has a first terminal that is configured to be coupled to the positive voltage (vₚ) when a first switch 524 is closed and that is further configured to be coupled to the negative voltage (vₙ) when a second switch 526 is closed. The first capacitor 522 has a second terminal that may be coupled to a first analog input signal (Vᵢₙₚ) when the first input switch 512 is closed.

The SAR ADC 500 can be configured to convert the voltage difference between a first analog input signal (Vᵢₙₚ) and second analog input signal (Vᵢₙₙ) in an analog-to-digital conversion operation that includes a sampling phase and a conversion phase.

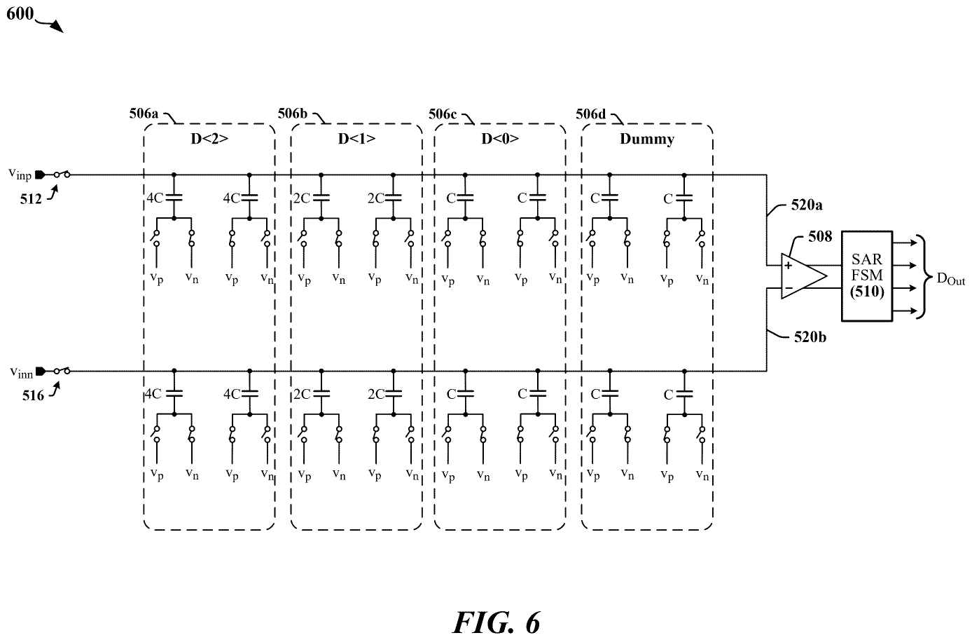

FIG. 6 illustrates a configuration 600 of the SAR ADC 500 when operating in the sampling phase. Two of the capacitors in each bit segment 506a, 506b, 506c are coupled to one of the reference voltages (i.e., vₚ or vₙ) and the other two capacitors in the bit segment 506a, 506b, 506c are coupled to the other reference voltages (i.e., vₙ or vₚ). Using the example of the MSB bit segment 506a, the first capacitor 522 in the first capacitive DAC 502 may be coupled to vₙ and a second capacitor 528 in the first capacitive DAC 502 may be coupled to vₚ in the sampling phase (see FIG. 5). Additionally, a first capacitor 530 in the second capacitive DAC 504 may be coupled to vₙ and a second capacitor 532 in the second capacitive DAC 504 may be coupled to vₚ in the sampling phase. One capacitor in each bit segment 506a, 506b, 506c is coupled between the vₚ reference voltage and a first input 520a of the comparator 508, and one capacitor in each bit segment 506a, 506b, 506c is coupled between the vₙ reference voltage and the first input 520a of the comparator 508. One capacitor in each bit segment 506a, 506b, 506c is coupled between the vₚ reference voltage and a second input 520b of the comparator 508, and one capacitor in each bit segment 506a, 506b, 506c is coupled between the vₙ reference voltage and the second input 520b of the comparator 508. Effectively, the inputs 520a 520b of the comparator 508 are each capacitively coupled to a reference voltage that may be represented or calculated as (vₚ+vₙ)/2 during the sampling phase.

The sampling phase is used to capture the voltages (Vᵢₙₚ and Vᵢₙₙ) of a differential input signal. The sampling phase commences when the input switches 512, 516 are closed (e.g., turned on or activated). When closed, a first input switch 512 couples the first analog input signal to a common node that is further coupled to a second terminal of each of the capacitors in the first capacitive DAC 502, and a second input switch 516 couples the second analog input signal to a common node that is further coupled to a second terminal of each of the capacitors in the second capacitive DAC 504. The input switches 512, 516 are then opened (e.g., turned off or deactivated).

The charge (Q_{sample_p}) stored on the capacitors coupled to the first input 520a of the comparator 508 may be calculated as:

$$\begin{matrix}{Q}_{sample \_ p} = ( ( {V}_{inp} - {v}_{p} ) \times 4 C ) + ( ( {V}_{inp} - {v}_{n} ) \times 4 C ) + \\ ( ( {V}_{inp} - {v}_{p} ) \times 2 C ) + ( ( {V}_{inp} - {v}_{n} ) \times 2 C ) + \\ ( ( {V}_{inp} - {v}_{p} ) \times C ) + ( ( {V}_{inp} - {v}_{n} ) \times C ) + \\ ( ( {V}_{inp} - {v}_{p} ) \times 2 C ) + ( ( {V}_{inp} - {v}_{n} ) \times 2 C ) \\ = ( ( {V}_{inp} - {v}_{p} ) \times 8 C ) + ( ( {V}_{inp} - {v}_{n} ) \times 8 C )\end{matrix} .$$

$$Substituting {v}_{ref} for ( {v}_{p} + {v}_{n} ) / 2 , then :$$

$${Q}_{sample \_ p} = ( {V}_{inp} - {v}_{ref} ) \times 16 C .$$

The charge (Q_{sample_n}) stored on the capacitors coupled to the second input 520b of the comparator 508 may be similarly calculated as:

$${Q}_{sample \_ n} = ( {V}_{inn} - {v}_{ref} ) \times 16 C .$$

The conversion phase commences when the SAR ADC 500 is configured substantially as shown in FIG. 6 and after the first input switch 512 and second input switch 516 are opened. When the input switches 512 and 516 are opened at the end of the sampling phase, the voltage Vᵢₙₚ(t₀) at the first input 520a of the comparator 508 may be calculated as:

$$\begin{matrix}{V}_{inp} ( {t}_{0} ) = \frac{( {V}_{inp} - {v}_{ref} ) \times 16 C}{16 C} + {v}_{ref} \\ = {V}_{inp}\end{matrix} .$$

When the input switches 512 and 516 are opened at the end of the sampling phase, the voltage Vᵢₙₙ(t₀) at the second input 520b of the comparator 508 may be calculated as:

$$\begin{matrix}{V}_{inn} ( {t}_{0} ) = \frac{( {V}_{inn} - {v}_{ref} ) \times 16 C}{16 C} + {v}_{ref} \\ = {V}_{inn}\end{matrix} .$$

The voltage state of Vᵢₙₚ is captured and held at the output of the first capacitive DAC 502 and Vᵢₙₙ is held at the output of the second capacitive DAC 504. The comparator 508 compares the first input voltage Vᵢₙₚ with the second input voltage Vᵢₙₙ, and outputs a difference signal based on the comparison. For example, the comparator 508 may output a first logic value (e.g., one) when the first input voltage Vᵢₙₚ is greater than the second input voltage Vᵢₙₙ, and output a second logic value (e.g., zero) when the second input voltage Vᵢₙₙ is greater than the first input voltage Vᵢₙₚ.

The SAR 510 may then determine a sign bit (D<3>) based on the difference signal indicating whether the first input voltage Vᵢₙₚ is greater than the second input voltage Vᵢₙₙ. For example, the sign bit may have a first logic value (e.g., one) if the difference signal indicates the first input voltage Vᵢₙₚ is greater than the second input voltage Vᵢₙₙ, and a second logic value (e.g., zero) if the second input voltage Vᵢₙₙ is greater than the first input voltage Vᵢₙₚ. The conversion phase may continue using a binary search technique such as the binary search illustrated in FIG. 4.

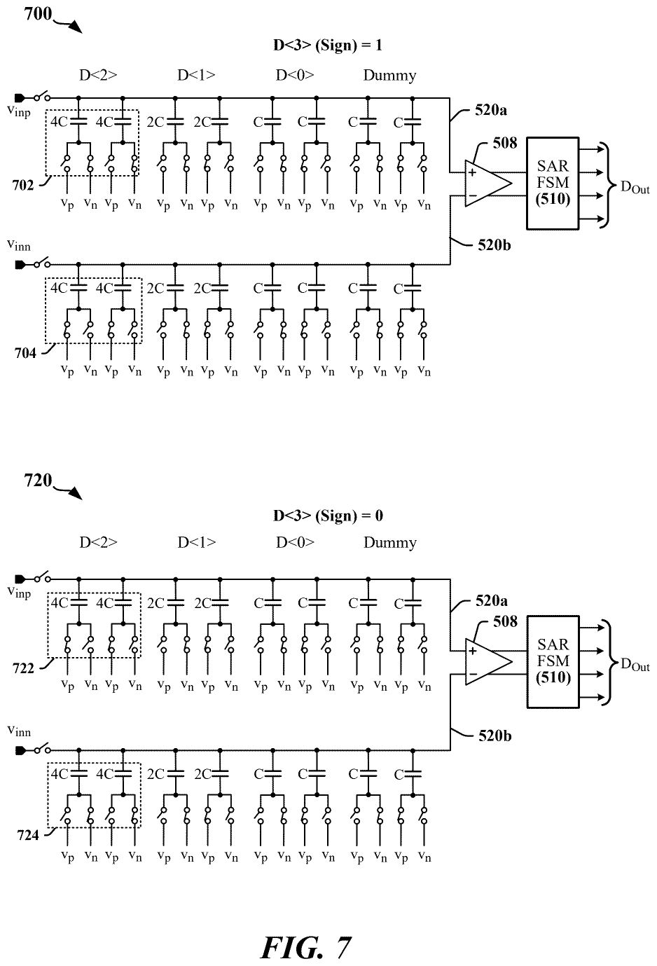

FIGS. 7-9 illustrate examples of configurations of the SAR ADC 500 that may be used during the conversion phase. The conversion phase commences when the SAR ADC 500 is configured substantially as shown in FIG. 5 and after the first input switch 512 and second input switch 516 are opened. The voltage state of Vᵢₙₚ is captured and held at the output of the first capacitive DAC 502 and Vᵢₙₙ is held at the output of the second capacitive DAC 504. The comparator 508 compares the first input voltage Vᵢₙₚ with the second input voltage Vᵢₙₙ, and outputs a difference signal based on the comparison. For example, the comparator 508 may output a first logic value (e.g., one) when the first input voltage Vᵢₙₚ is greater than the second input voltage Vᵢₙₙ, and output a second logic value (e.g., zero) when the second input voltage Vᵢₙₙ is greater than the first input voltage Vᵢₙₚ.

A first configuration 700 shown in FIG. 7 may be used when D<3>=1. In this configuration 700, the first input 520a of the comparator 508 is coupled to the vₙ reference voltage through the first capacitors 702 associated with the D<2> bit segment 506a, and the second input 520b of the comparator 508 is coupled to the vₚ reference voltage through the second capacitors 704 associated with the D<2> bit segment 506a. In this configuration 700, the voltage Vᵢₙₚ(t₁) at the first input 520a of the comparator 508 may be calculated as:

$$\begin{matrix}{V}_{inp} ( {t}_{1} ) = {V}_{inp} ( {t}_{0} ) - ( {V}_{ref} \frac{4 C}{16 C} ) \\ = {V}_{inp} ( {t}_{0} ) - \frac{1}{4} {V}_{ref}\end{matrix} .$$

where Vᵢₙₚ(t₀) is the voltage at the first input 520a of the comparator 508 during sign determination (i.e., D<3>). In this configuration 700, the voltage Vᵢₙₙ(t₁) at the second input 520b of the comparator 508 may be calculated as:

$$\begin{matrix}{V}_{inn} ( {t}_{1} ) = {V}_{inn} ( {t}_{0} ) + ( {V}_{ref} \frac{4 C}{16 C} ) \\ = {V}_{inn} ( {t}_{0} ) + \frac{1}{4} {V}_{ref}\end{matrix} .$$

where Vᵢₙₙ(t₀) is the voltage at the second input 520b of the comparator 508 during sign determination (i.e., D<3>). In this configuration 700, the voltage difference between the inputs 520a and 520b of the comparator 508 may be calculated as:

$${V}_{inp} ( {t}_{1} ) - {V}_{inn} ( {t}_{1} ) = {V}_{inp} ( {t}_{0} ) - {V}_{inn} ( {t}_{0} ) - \frac{1}{2} {V}_{ref} .$$

A second configuration 720 shown in FIG. 7 may be used when D<3>=0. In this configuration 720, the first input 520a of the comparator 508 is coupled to the vₚ reference voltage through the first capacitors 722 associated with the D<2> bit segment 506a, and the second input 520b of the comparator 508 is coupled to the vₙ reference voltage through the second capacitors 724 associated with the D<2> bit segment 506a. In this configuration 720, the voltage Vᵢₙₚ(t₁) at the first input 520a of the comparator 508 may be calculated as:

$$\begin{matrix}{V}_{inp} ( {t}_{1} ) = {V}_{inp} ( {t}_{0} ) + ( {V}_{ref} \frac{4 C}{16 C} ) \\ = {V}_{inp} ( {t}_{0} ) + \frac{1}{4} {V}_{ref}\end{matrix} .$$

In this configuration 720, the voltage Vᵢₙₙ(t₁) at the second input 520b of the comparator 508 may be calculated as:

$$\begin{matrix}{V}_{inn} ( {t}_{1} ) = {V}_{inn} ( {t}_{0} ) - ( {V}_{ref} \frac{2 C}{8 C} ) \\ = {V}_{inn} ( {t}_{0} ) - \frac{1}{4} {V}_{ref}\end{matrix} .$$

In this configuration 720, the voltage difference between the inputs 520a and 520b of the comparator 508 may be calculated as:

$${V}_{inp} ( {t}_{1} ) - {V}_{inn} ( {t}_{1} ) = {V}_{inp} ( {t}_{0} ) - {V}_{inn} ( {t}_{0} ) + \frac{1}{2} {V}_{ref} .$$

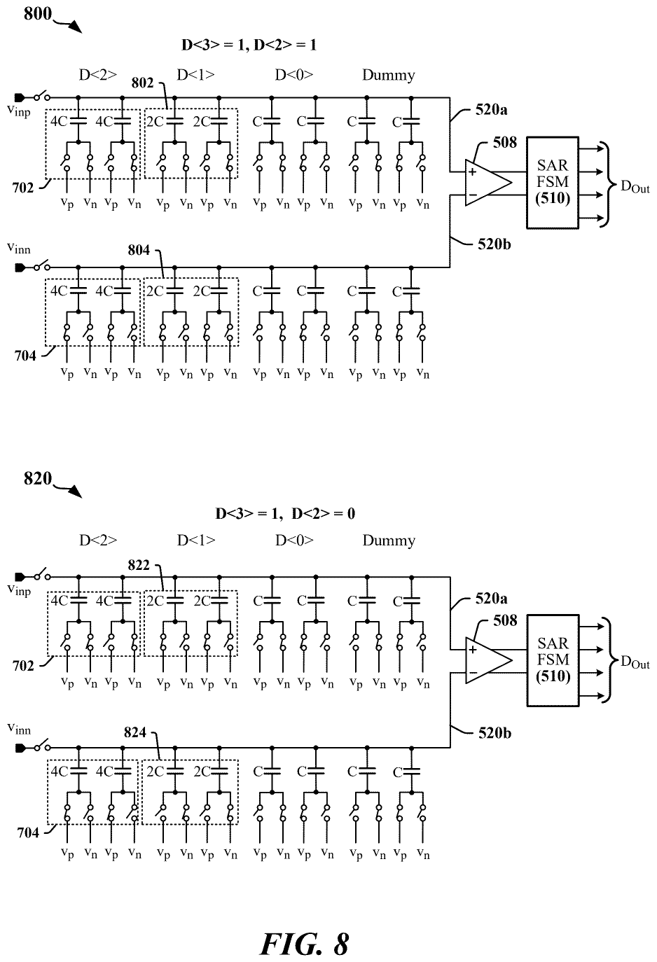

A first configuration 800 shown in FIG. 8 may be used when D<3>=D<2>=1. In this configuration 800, the first input 520a of the comparator 508 remains coupled to the vₙ reference voltage through the first capacitors 702 associated with the D<2> bit segment 506a, and the second input 520b of the comparator 508 remains coupled to the vₚ reference voltage through the second capacitors 704 associated with the D<2> bit segment 506a. The first input 520a of the comparator 508 is also coupled to the vₙ reference voltage through the first capacitors 802 associated with the D<1> bit segment 506b, and the second input 520b of the comparator 508 is also coupled to the vₚ reference voltage through the second capacitors 804 associated with the D<1> bit segment 506b. In this configuration 800, the voltage Vᵢₙₚ(t₂) at the first input 520a of the comparator 508 may be calculated as:

$$\begin{matrix}{V}_{inp} ( {t}_{2} ) = {V}_{inp} ( {t}_{0} ) - ( {V}_{ref} \frac{4 C}{16 C} ) - ( {V}_{ref} \frac{2 C}{16 C} ) \\ = {V}_{inp} ( {t}_{0} ) - \frac{3}{8} {V}_{ref}\end{matrix} .$$

In this configuration 800, the voltage Vᵢₙₙ(t₂) at the second input 520b of the comparator 508 may be calculated as:

$$\begin{matrix}{V}_{inn} ( {t}_{2} ) = {V}_{inn} ( {t}_{0} ) + ( {V}_{ref} \frac{4 C}{16 C} ) + ( {V}_{ref} \frac{2 C}{16 C} ) \\ = {V}_{inn} ( {t}_{0} ) + \frac{3}{8} {V}_{ref}\end{matrix} .$$

In this configuration 800, the voltage difference between the inputs 520a and 520b of the comparator 508 may be calculated as:

$${V}_{inp} ( {t}_{2} ) - {V}_{inn} ( {t}_{2} ) = {V}_{inp} ( {t}_{0} ) - {V}_{inn} ( {t}_{0} ) - \frac{3}{4} {V}_{ref} .$$

A second configuration 820 shown in FIG. 8 may be used when D<3>=1 and D<2>=0. In this configuration 820, the first input 520a of the comparator 508 remains coupled to the vₙ reference voltage through the first capacitors 702 associated with the D<2> bit segment 506a, and the second input 520b of the comparator 508 remains coupled to the vₚ reference voltage through the second capacitors 704 associated with the D<2> bit segment 506a. The first input 520a of the comparator 508 is coupled to the vₚ reference voltage through the first capacitors 822 associated with the D<1> bit segment 506b, and the second input 520b of the comparator 508 is coupled to the vₙ reference voltage through the second capacitors 824 associated with the D<1> bit segment 506b. In this configuration 820, the voltage Vᵢₙₚ(t₂) at the first input 520a of the comparator 508 may be calculated as:

$$\begin{matrix}{V}_{inp} ( {t}_{2} ) = {V}_{inp} ( {t}_{0} ) - ( {V}_{ref} \frac{4 C}{16 C} ) + ( {V}_{ref} \frac{2 C}{16 C} ) \\ = {V}_{inp} ( {t}_{0} ) - \frac{1}{8} {V}_{ref}\end{matrix} .$$

In this configuration 820, the voltage Vᵢₙₙ(t₂) at the second input 520b of the comparator 508 may be calculated as:

$$\begin{matrix}{V}_{inn} ( {t}_{2} ) = {V}_{inn} ( {t}_{0} ) - ( {V}_{ref} \frac{4 C}{16 C} ) - ( {V}_{ref} \frac{2 C}{16 C} ) \\ = {V}_{inn} ( {t}_{0} ) + \frac{1}{8} {V}_{ref}\end{matrix} .$$

In this configuration 820, the voltage difference between the inputs 520a and 520b of the comparator 508 may be calculated as:

$${V}_{inp} ( {t}_{2} ) - {V}_{inn} ( {t}_{2} ) = {V}_{inp} ( {t}_{0} ) - {V}_{inn} ( {t}_{0} ) - \frac{1}{4} {V}_{ref} .$$

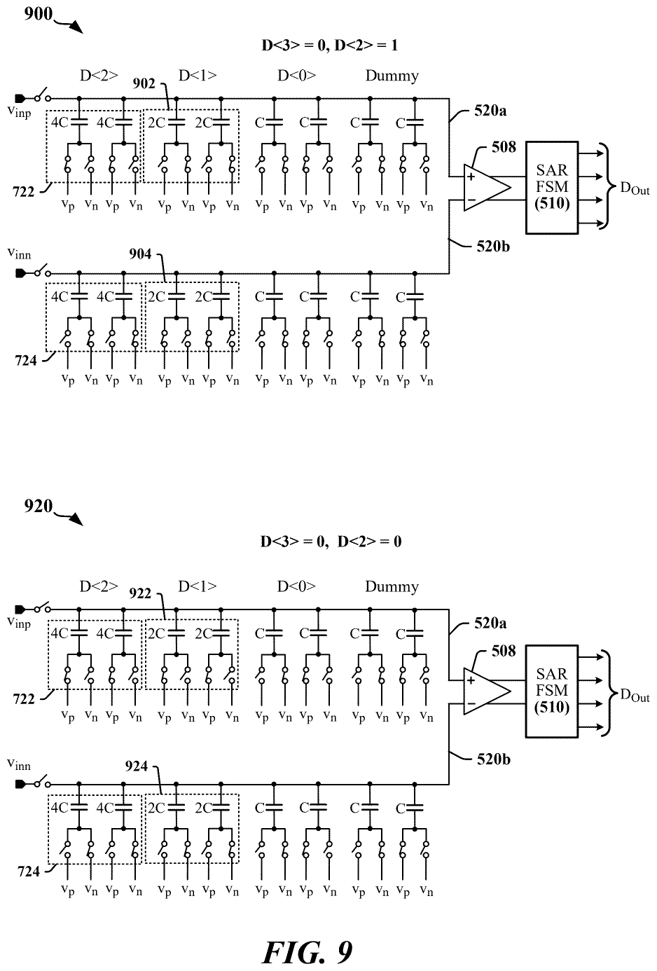

A first configuration 900 shown in FIG. 9 may be used when D<3>=0 and D<2>=1. In this configuration 900, the first input 520a of the comparator 508 is coupled to the vₚ reference voltage through the first capacitors 722 associated with the D<2> bit segment 506a, and the second input 520b of the comparator 508 is coupled to the vₙ reference voltage through the second capacitors 724 associated with the D<2> bit segment 506a. The first input 520a of the comparator 508 is coupled to the vₙ reference voltage through the first capacitors 902 associated with the D<1> bit segment 506b, and the second input 520b of the comparator 508 is coupled to the vₚ reference voltage through the second capacitors 904 associated with the D<1> bit segment 506b. In this configuration 900, the voltage Vᵢₙₚ(t₂) at the first input 520a of the comparator 508 may be calculated as:

$$\begin{matrix}{V}_{inp} ( {t}_{2} ) = {V}_{inp} ( {t}_{0} ) + ( {V}_{ref} \frac{4 C}{16 C} ) - ( {V}_{ref} \frac{2 C}{16 C} ) \\ = {V}_{inp} ( {t}_{0} ) + \frac{1}{8} {V}_{ref}\end{matrix} .$$

In this configuration 900, the voltage Vᵢₙₙ(t₂) at the second input 520b of the comparator 508 may be calculated as:

$$\begin{matrix}{V}_{inn} ( {t}_{2} ) = {V}_{inn} ( {t}_{0} ) - ( {V}_{ref} \frac{4 C}{16 C} ) + ( {V}_{ref} \frac{2 C}{16 C} ) \\ = {V}_{inn} ( {t}_{0} ) - \frac{1}{8} {V}_{ref}\end{matrix} .$$

In this configuration 900, the voltage difference between the inputs 520a and 520b of the comparator 508 may be calculated as:

$${V}_{inp} ( {t}_{2} ) - {V}_{inn} ( {t}_{2} ) = {V}_{inp} ( {t}_{0} ) - {V}_{inn} ( {t}_{0} ) + \frac{1}{4} {V}_{ref} .$$

A second configuration 920 shown in FIG. 9 may be used when D<3>=0 and D<2>=0. In this configuration 920, the first input 520a of the comparator 508 is coupled to the vₚ reference voltage through the first capacitors 722 associated with the D<2> bit segment 506a, and the second input 520b of the comparator 508 is coupled to the vₙ reference voltage through the second capacitors 724 associated with the D<2> bit segment 506a. The first input 520a of the comparator 508 is coupled to the vₚ reference voltage through the first capacitors 922 associated with the D<1> bit segment 506b, and the second input 520b of the comparator 508 is coupled to the vₙ reference voltage through the second capacitors 924 associated with the D<1> bit segment 506b. In this configuration 920, the voltage Vᵢₙₚ(t₂) at the first input 520a of the comparator 508 may be calculated as:

$$\begin{matrix}{V}_{inp} ( {t}_{2} ) = {V}_{inp} ( {t}_{0} ) + ( {V}_{ref} \frac{4 C}{16 C} ) + ( {V}_{ref} \frac{2 C}{16 C} ) \\ = {V}_{inp} ( {t}_{0} ) + \frac{3}{8} {V}_{ref}\end{matrix} .$$

In this configuration 920, the voltage Vᵢₙₙ(t₂) at the second input 520b of the comparator 508 may be calculated as:

$$\begin{matrix}{V}_{inn} ( {t}_{2} ) = {V}_{inn} ( {t}_{0} ) - ( {V}_{ref} \frac{4 C}{16 C} ) - ( {V}_{ref} \frac{2 C}{16 C} ) \\ = {V}_{inn} ( {t}_{0} ) - \frac{3}{8} {V}_{ref}\end{matrix} .$$

In this configuration 920, the voltage difference between the inputs 520a and 520b of the comparator 508 may be calculated as:

$${V}_{inp} ( {t}_{2} ) - {V}_{inn} ( {t}_{2} ) = {V}_{inp} ( {t}_{0} ) - {V}_{inn} ( {t}_{0} ) + \frac{3}{4} {V}_{ref} .$$

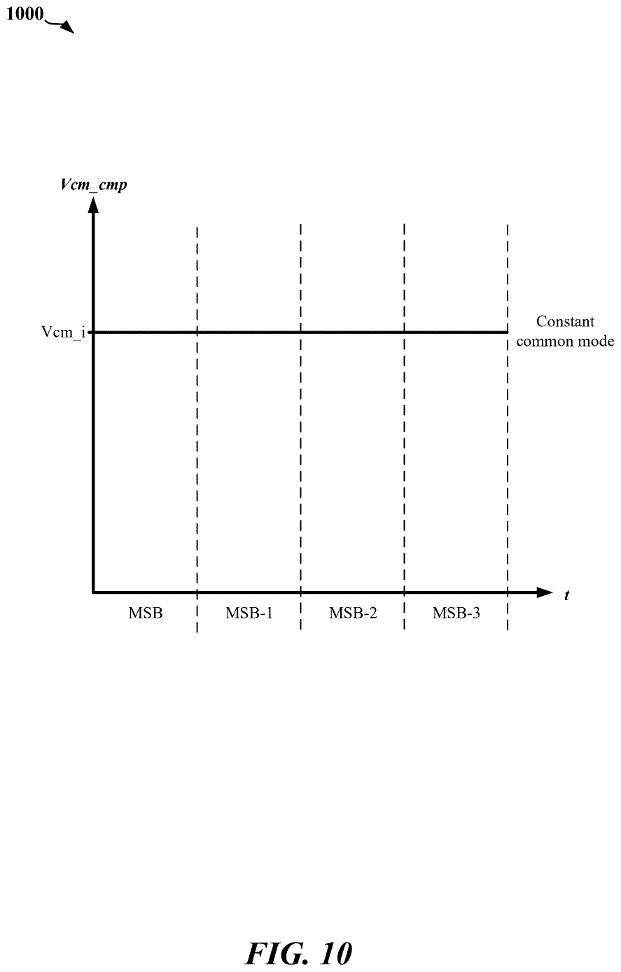

FIG. 10 includes a graph 1000 that shows an example of common mode voltage at the input of the comparator 508. It can be expected the expected the common mode voltage remains constant when symmetric capacitance switching is implemented (see, for example, FIGS. 5-9) in the capacitive DACs used by the SAR ADC 500. Symmetric capacitance switching can mitigate nonlinear effects from charge injection and comparator kickback noise. However, certain disadvantages are associated with the use of symmetric capacitance switching in the capacitive DAC. A large area of semiconductor die is needed to implement the large number of capacitors. For example, a 4-bit capacitive DAC requires the equivalent of 32 capacitors that provide unit capacitance. Additionally, large capacitive loading is coupled to the input to the capacitive DAC, and increased switching-related glitches can be expected on the reference voltage as the number of capacitors and/or size of capacitance increases. These issues typically escalate as bit resolutions increase and can prevent capacitive DACs from supporting conversions that provide greater than 10-bit resolution (e.g., 12-bit resolution).

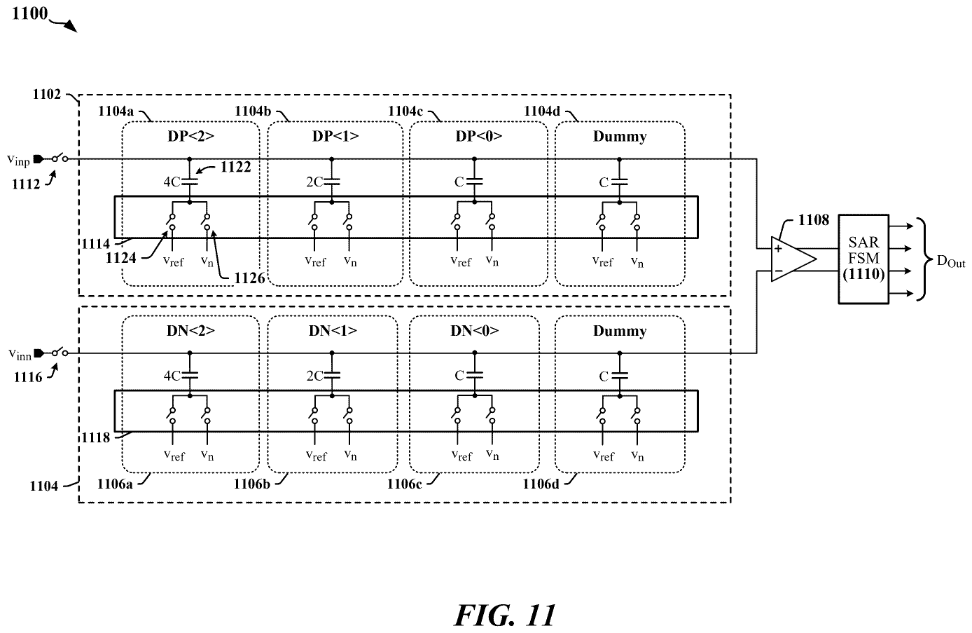

Certain conventional SAR ADCs are designed with an asymmetric capacitance switching scheme. FIG. 11 illustrates an example of asymmetric capacitance switching in a differential SAR ADC 1100 that is implemented using capacitive DACs 1102, 1104. The illustrated SAR ADC 1100 includes a first capacitive DAC 1102, a second capacitive DAC 1104, a comparator 1108, a SAR 1110, a first input switch 1112, and a second input switch 1116. In the illustrated example, a first switching circuit 1114 can be operated to selectively couple capacitors in the first capacitive DAC 1102 to a negative voltage (vₙ) and a reference voltage (v_{ref}). The v_{ref} reference voltage may correspond to a positive voltage (vₚ) or to an intermediate voltage such as (vₚ+vₙ)/2. The SAR 1110 may include or cooperate with a finite state machine, a processor, sequencing logic and/or other logic circuits that can configure the first input switch 1112, the second input switch 1116, the first switching circuit 1114 and the second switching circuit 1118 based on a current state of operation of the differential SAR ADC 1100.

The first capacitive DAC 1102 includes three binary-weighted bit segments 1104a, 1104b, 1104c and a dummy bit segment 1104d. The second capacitive DAC 1104 includes three binary-weighted bit segments 1106a, 1106b, 1106c and a dummy bit segment 1106d. Each of the bit segments 1104a, 1104b, 1104c, 1104d, 1106a, 1106b, 1106c, 1104d include a single switched capacitor. Switched capacitances are configured to define weights provided by the bit segments 1104a-1104d and 1106a-1106d. Binary weighting is defined by capacitance.

In the illustrated example, the least significant bit (LSB) bit segments 1104c, 1106c may be assigned a binary weight of 1 and each includes a capacitor that provides a smallest capacitance, which may be defined or referred to as the unit capacitance. The next bit segments 1104b, 1106b may be assigned a binary weight of 2 and each of these includes a capacitor that provides a capacitance that is that is two times greater than the unit capacitance. The most significant bit (MSB) bit segments 1104a, 1106a may be assigned a binary weight of 4 and each of these includes a capacitor that provides a capacitance that is four times greater than the unit capacitance.

In the illustrated SAR ADC 1100, the first capacitive DAC 1102 includes a first switching circuit 1114 that includes switches that are coupled to the first terminal of the capacitors in the first capacitive DAC 1102. The second capacitive DAC 1104 includes a second switching circuit 1118 that includes switches that are coupled to the first terminal of the capacitors in the second capacitive DAC 1104. In the illustrated example, switches in the switching circuits 1114, 1118 enable the first terminal of each capacitor to be selectively coupled to a reference voltage (v_{ref}) or the negative voltage (vₙ). In this example, a capacitor 1122 in the MSB bit segment 1104a has one terminal that is configured to be coupled to the reference voltage (v_{ref}) when a first switch 1124 is closed and further configured to be coupled to the negative voltage (vₙ) when a second switch 1126 is closed. The capacitor 1122 has a second terminal that may be coupled to a first analog input signal (Vᵢₙₚ) when the first input switch 1112 is closed. In other implementations, the first terminal of each capacitor to be selectively coupled to a reference voltage (v_{ref}) or the positive voltage (vₚ).

The SAR ADC 1100 can be configured to convert the voltage difference between a first analog input signal (Vᵢₙₚ) and second analog input signal (Vᵢₙₙ) to a digital representation in an analog-to-digital conversion operation that includes a sampling phase and a conversion phase. In the sampling phase, the capacitor in each bit segment 1104a-1104d of the first capacitive DAC 1102 is coupled to the reference voltage (v_{ref}). The conversion phase corresponds in many respects to the conversion phase in a SAR ADC 500 that includes capacitive DACs configured for symmetric capacitance switching (see FIG. 5).

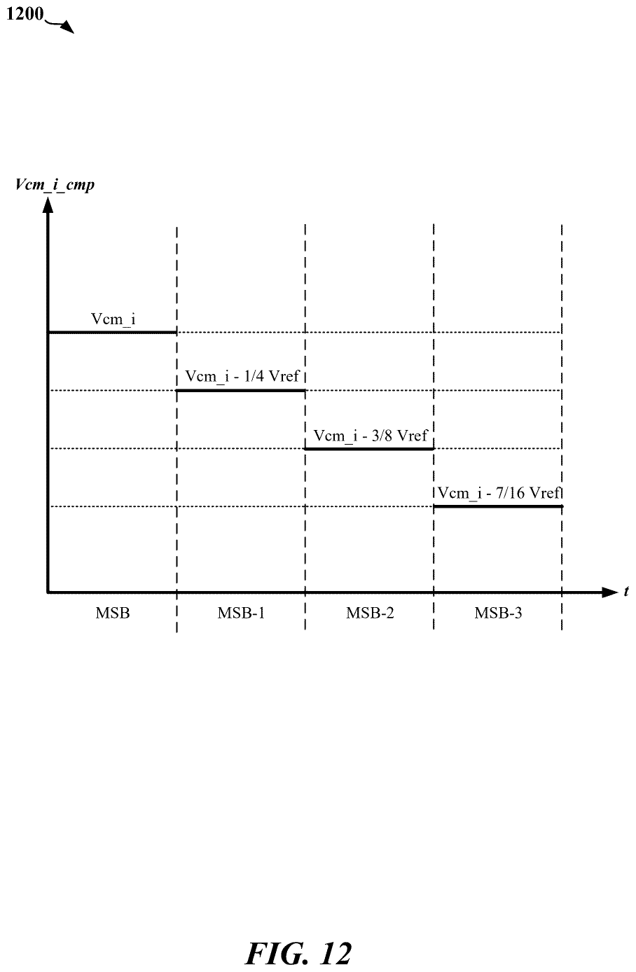

In some instances, the area of a semiconductor die can be reduced by 50% when asymmetric capacitance switching is implemented. However, the use of asymmetric capacitance switching can result in a variable common mode voltage at the at the input of the comparator 1108. The graph 1200 shown in FIG. 12 illustrates a decreasing common mode voltage at the input of the comparator 1108 when the capacitors of the capacitive DACs 1102 and 1104 are switched between the negative voltage (vₙ) and the reference voltage (v_{ref}). In the example illustrated by FIG. 12, the input common mode voltage is decreased for each bit conversion. In another example, an increasing common mode voltage can be expected at the input of the comparator 1108 when the capacitors of the capacitive DACs 1102 and 1104 are switched between a positive voltage (vₚ) and the reference voltage (v_{ref}). In this other example, the input common mode voltage can be expected to increase for each bit conversion.

The implementation of asymmetric capacitance switching can cause the sensitivity to charge injection and kick noise of the SAR ADC 1100 to increase relative to the SAR ADC 500 in which symmetric capacitance is employed. The potential for variable common mode voltage may require a more complex comparator design, and may result in increased power consumption. In some examples, the SAR ADC 1100 may have a 6 dB or greater reduction in sensitivity than the more conventional SAR ADC 500.

Certain aspects of this disclosure relate to the use of a capacitive DAC that implements a hybrid capacitance switching scheme. The use of hybrid capacitance switching in capacitive DACs may enable a SAR ADC to maintain a full-scale input range that matches the input range of a conventional SAR ADC structure with a consistent common mode voltage.

Capacitive DACs provided in accordance with certain aspects of this disclosure can be coupled to respective complementary inputs of a SAR ADC. Each bit segment provides a capacitor that can be selectively coupled between a corresponding complementary input and one of multiple voltages. The capacitor in each bit segment other than the LSB bit segment can be selectively coupled to one of three different voltages that include a positive voltage (vₚ), a negative voltage (vₙ) and a reference voltage (v_{ref}). The capacitors in the bit segment associated with each bit weight are switched in a complementary manner, whereby the capacitors in the bit segment are coupled to different voltages (e.g., vₚ or vₙ) except when both capacitors are coupled to the reference voltage (v_{ref}). This feature enables a 50% reduction of capacitance provided by each bit segment, with respect to a comparable conventional SAR ADC (see, e.g., the SAR ADC 500 shown in FIG. 5).

The capacitor in the LSB bit segment can be selectively coupled to one of two voltages that includes the reference voltage (v_{ref}) and either the positive voltage (vₚ) or the negative voltage (vₙ). In all operating states, at least one of the capacitors in the LSB bit segment is coupled to the reference voltage (v_{ref}). Accordingly, a reference voltage is always available to the comparator used to compare the voltages at the outputs of the capacitive DACs. In one example, each capacitor in the LSB bit segment and in the LSB+1 bit segment may be configured with the same capacitance (C). The LSB+1 bit segment may be associated with the second least significant bit resolved by the SAR ADC. The binary switching of the LSB bit segment (i.e., one capacitor remains coupled to v_{ref}) produces half the effect on voltage measured at a comparator than the complementary switching of the capacitors in the LSB+1 bit segment.

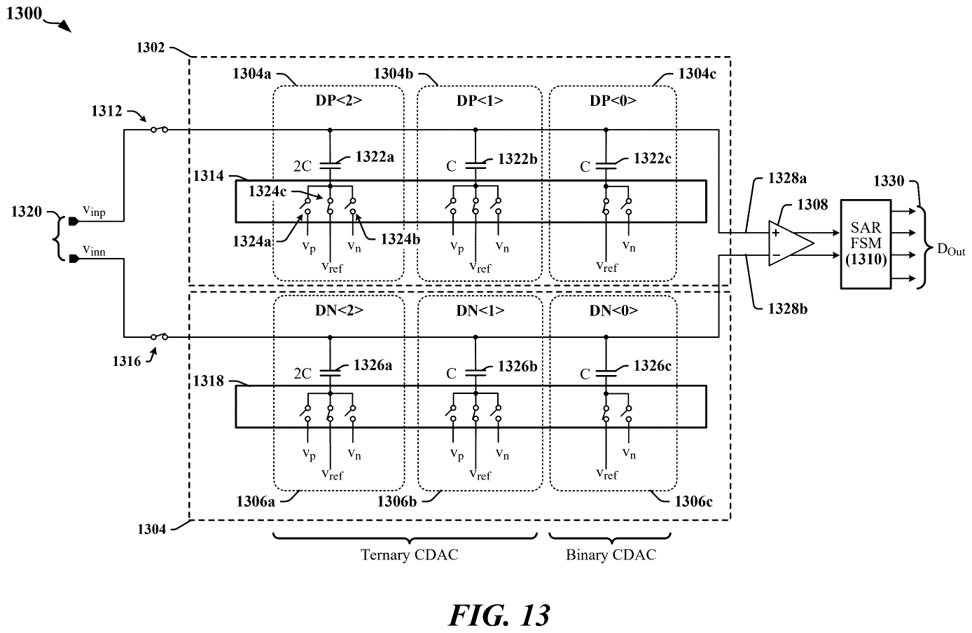

A hybrid capacitance switching scheme that includes binary control of the LSB bit segments and complementary control of other bit segments can enable a further 50% reduction of capacitance provided by each bit segment, with respect to a comparable conventional SAR ADC. For example, the SAR ADC 500 shown in FIG. 5 requires a total capacitance of 32C to produce 4-bit resolution of an analog input, whereas a SAR ADC provided in accordance with certain aspects of this disclosure (e.g., see the SAR ADC 1300 shown in FIG. 13) uses a total capacitance of 8C to produce a 4-bit resolution of the analog input.

Complementary switching of the non-LSB bit segments can enable the capacitive DAC to maintain a constant common mode voltage at the comparator input for all bit conversions, with the sole exception of LSB conversions. LSB conversions may produce a negligible change in comparator common mode voltage for 12-bit ADCs. According to one aspect, the hybrid capacitance switching scheme is implemented using bit segments that each include a single switched capacitor.

FIG. 13 illustrates a first example of SAR ADC 1300 that can implement a hybrid capacitance switching scheme in accordance with certain aspects of this disclosure. The SAR ADC 1300 is implemented using capacitive DACs 1302, 1304 configured to receive a differential input signal 1320 through input switches 1312, 1316. The illustrated SAR ADC 1300 includes a first capacitive DAC 1302, a second capacitive DAC 1304, a comparator 1308 and a SAR 1310. A first switching circuit 1314 may be operated to selectively couple capacitors in the first capacitive DAC 1302 to a positive voltage (vₚ), a negative voltage (vₙ) or a common-mode reference voltage (v_{ref}). A second switching circuit 1318 may be operated to selectively couple capacitors in the second capacitive DAC 1304 to the positive voltage (vₚ), the negative voltage (vₙ) or the common-mode reference voltage (v_{ref}). In certain implementations, the voltage level of the common-mode reference voltage may be defined or calculated as v_{cm_ref}=(vₚ+vₙ)/2. In some implementations, the designated reference voltage may be provided at circuit ground or another voltage level. The SAR 1310 may include or cooperate with a finite state machine (FSM), a processor, sequencing logic and/or other logic circuits that can configure the first input switch 1312, the second input switch 1316, the first switching circuit 1314 and the second switching circuit 1318 based on a current state of operation of the SAR ADC 1300.

The first capacitive DAC 1302 includes three binary-weighted bit segments 1304a, 1304b, 1304c. The second capacitive DAC 1304 includes three binary-weighted bit segments 1306a, 1306b, 1306c. According to one aspect, the capacitive DACs 1302, 1304 do not include or require a dummy bit segment. Each of the bit segments 1304a-1304c and 1306a-1306c includes a single switched capacitor 1322a-1322c, 1326a-1326c. The capacitances of the switched capacitors 1322a-1322c, 1326a-1326c are configured to define the binary weights provided by the bit segments 1304a-1304c and 1306a-1306c. For the purposes of this description, switched capacitances may include capacitors that each have a first plate and a second plate that can be coupled to external circuits through a first terminal and a second terminal, respectively. In some implementations, the switched capacitances may switch capacitances may provide capacitance using some combination of capacitors, transistors, diodes and/or sources of parasitic capacitance.

In the illustrated example, the least significant bit (LSB) bit segments 1304c, 1306c may be assigned a binary weight of 1 and each of these includes a switched capacitor 1322c, 1326c that provides a smallest capacitance, which may be referred to as the unit capacitance. The next bit segments 1304b, 1306b may be assigned a binary weight of 2 and each of these includes a capacitor 1322b, 1326b that provides a capacitance that is that is the same as the unit capacitance. The most significant bit (MSB) bit segments 1304a, 1306a may be assigned a binary weight of 4 and each of these includes a capacitor 1322a, 1326a that provides a capacitance that is two times greater than the unit capacitance.

In the illustrated SAR ADC 1300, the first capacitive DAC 1302 includes a first switching circuit 1314 that includes switches that are coupled to a first terminal of the capacitors 1322a-1322c in the first capacitive DAC 1302. The second capacitive DAC 1304 includes a second switching circuit 1318 that includes switches that are coupled to the first terminal of the capacitors 1326a-1326c in the second capacitive DAC 1304. For all but the LSB bit segments 1304c and 1306c, switches in the switching circuits 1314, 1318 enable the first terminal of each capacitor 1322a, 1322b, 1326a, 1326b to be selectively coupled to the positive voltage (vₚ), the negative voltage (vₙ), or the common-mode reference voltage (v_{ref}). In the illustrated example, a capacitor 1322a in the MSB bit segment 1304a has a first terminal that is configured to be coupled to the positive voltage (vₚ) when a first switch 1324a is closed, to the negative voltage (vₙ) when a second switch 1324b is closed and to the common-mode reference voltage (v_{ref}) when a third switch 1324c is closed. Switches in the switching circuits 1314, 1318 enable the first terminal of each capacitor 1322c and 1326c in the LSB bit segments 1304c and 1306c to be selectively coupled to vₚ, vₙ or v_{ref}.

In some implementations, the switches in the switching circuits 1314, 1318 may be controlled using control codes defined for each bit segment 1304a-1304c, 1306a-1306c. In one example, switches associated with the LSB bit segments 1304c and 1306c may be controlled using encoded single-bit binary numbers that are configured to activate or turn on a switch coupled to vₚ, vₙ or v_{ref} in order to provide a desired reference voltage to the capacitors 1322c and 1326c in the LSB bit segments 1304c and 1306c. In another example, switches associated with the non-LSB bit segments 1304a, 1304b, 1306a and 1306b may be controlled using ternary numbers that are configured to select the reference voltage that is coupled to the capacitors 1322a, 1322b, 1326a, 1326b from vₚ, vₙ and v_{ref}.

A ternary number may refer to a base 3 number. A ternary number can represent one of three values, which may be expressed as the base 10 numbers ‘0’, ‘1’ and ‘2’. According to one aspect, a ternary number may be encoded using two binary bits in a digital circuit. For example, the digital circuit may represent the three possible values of a ternary number as ‘0b00’, ‘0b01’ and ‘0b10’, with the bit combination ‘0b11’ being unused. In the latter example, a ternary number can be used to select one of the three switches in a corresponding bit segment 1304a-1304c and 1306a-1306c at any time. For the purposes of this disclosure, each of the capacitive DACs 1302, 1304 may be characterized as including a ternary capacitive DAC (ternary CDAC) that includes non-LSB bit segments (e.g., bit segments 1304a, 1304b, 1306a and 1306b), and an LSB binary capacitive DAC (Binary CDAC) that includes only the LSB bit segments 1304c and 1306c.

The SAR ADC 1300 can be configured to convert the voltage difference between a first analog input signal (Vᵢₙₚ) and second analog input signal (Vᵢₙₙ) in an analog-to-digital conversion operation that includes a sampling phase and a conversion phase. The SAR ADC 1300 illustrated in FIG. 13 is configured for the sampling phase. In the sampling phase, each of the capacitors 1322a, 1322b, 1322c, 1326a, 1326b and 1326c is coupled to v_{ref}. At the start of the sampling phase, the FSM or other processing circuit associated with the SAR 1310, may configure the switching circuits 1314, 1318 to couple the first terminals each capacitor 1322a-1322c, 1326a-1326c to v_{ref}. The FSM or other processing circuit may then close the first and second input switches 1312 and 1316. The first input voltage (Vᵢₙₚ) is applied to the second terminal of each capacitor 1322a-1322c of the first capacitive DAC 1302 and the second input voltage (Vᵢₙₙ) is applied to the second terminal of each capacitor 1326a-1326c of the second capacitive DAC 1304. The second terminal of each capacitor 1322a-1322c of the first capacitive DAC 1302 is coupled to a first input of the comparator 1308 and the second terminal of each capacitor 1326a-1326c of the second capacitive DAC 1304 is coupled to a second input of the comparator 1308.

The conversion phase commences when the SAR ADC 1300 is configured substantially as shown in FIG. 13 and after the first input switch 1312 and second input switch 1316 are opened. The charge (Q_{sample_p}) stored on the capacitors coupled to the first input 1328a of the comparator 1308 may be calculated as:

$${Q}_{sample \_ p} = ( {V}_{inp} - {v}_{ref} ) \times 8 C .$$

The charge (Q_{sample_n}) stored on the capacitors coupled to the second input 1328b of the comparator 1308 may be similarly calculated as:

$${Q}_{sample \_ n} = ( {V}_{inn} - {v}_{ref} ) \times 8 C .$$

When the input switches 1312 and 1316 are opened at the end of the sampling phase, the voltage Vᵢₙₚ(t₀) at the first input 1328a of the comparator 1308 may be calculated as:

$$\begin{matrix}{V}_{inp} ( {t}_{0} ) = \frac{( {V}_{inp} - {v}_{ref} ) \times 8 C}{8 C} + {v}_{ref} \\ = {V}_{inp}\end{matrix} .$$

When the input switches 1312 and 1316 are opened at the end of the sampling phase, the voltage Vᵢₙₙ(t₀) at the second input 1328b of the comparator 1308 may be calculated as:

$$\begin{matrix}{V}_{inn} ( {t}_{0} ) = \frac{( {V}_{inn} - {v}_{ref} ) \times 8 C}{8 C} + {v}_{ref} \\ = {V}_{inn}\end{matrix} .$$

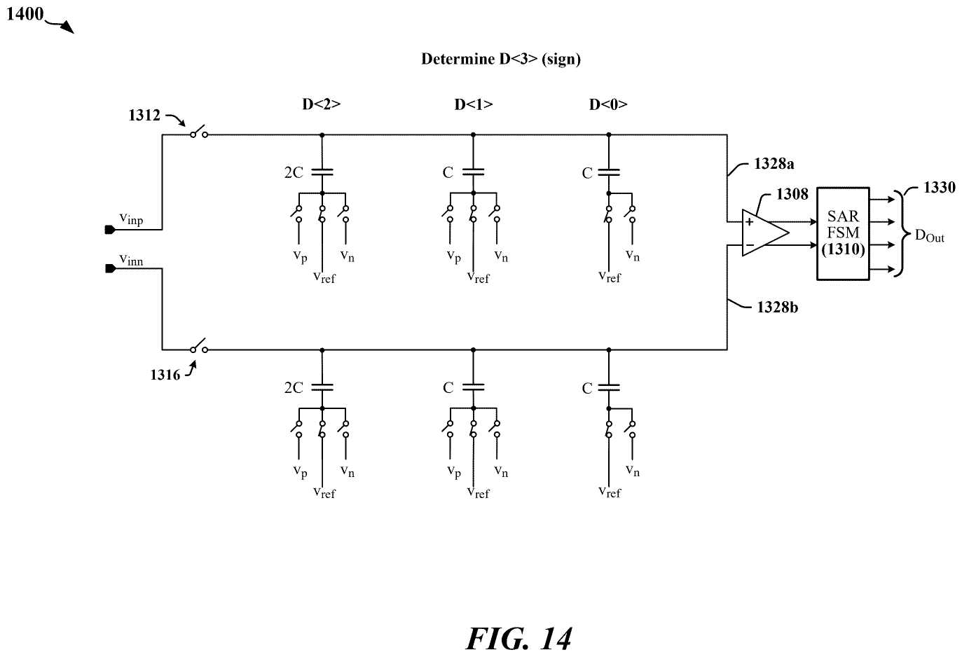

FIG. 14 shows a configuration 1400 of the SAR ADC 1300 that may be used to determine sign of the differential input signal 1320. The sampled voltage state of Vᵢₙₚ is provided to a first input 1328a of the comparator 1308 and the sampled voltage state of Vᵢₙₙ is provided to a second input 1328b of the comparator 1308. The comparator 1308 is configured to compare the voltages at its inputs 1328a, 1328b and to provide an output that indicates a sign of the difference between Vᵢₙₚ and Vᵢₙₙ when the SAR ADC 1300 is configured as shown in FIG. 14. For example, the comparator 1308 may output a first logic value (e.g., one) when the first input voltage Vᵢₙₚ is greater than the second input voltage Vᵢₙₙ, and output a second logic value (e.g., zero) when the second input voltage Vᵢₙₙ is greater than the first input voltage Vᵢₙₚ. The SAR 1310 may provide a sign bit (D<3>) in the digital output 1330 of the SAR ADC 1300. In one example, the sign bit encodes the difference between Vᵢₙₚ and Vᵢₙₙ.

The conversion phase may continue by comparing the difference between the sampled first input voltage and the sampled second input voltage (i.e., Vᵢₙₚ−Vᵢₙₙ) with a threshold voltage provided by switching one of the capacitors 1322a or 1326a in the MSB bit segments 1304a, 1306a from V_{ref} to vₚ and switching the other capacitor 1326a or 1322a in the MSB bit segments 1304a, 1306a from V_{ref} to vₙ, as indicated by the sign bit. The voltage difference between the sampled first input voltage and the sampled second input voltage can be expected to change when the capacitors 1322a or 1326a are switched to different reference voltages. The output of the comparator 1308 indicates whether the difference between Vᵢₙₚ and Vᵢₙₙ exceeds a threshold voltage level defined by the capacitors 1322a or 1326a. If the threshold voltage level exceeds the difference between Vᵢₙₚ and Vᵢₙₙ, then the search may continue with a reduced threshold voltage level. The SAR 1310 may use this process to resolve a digital representation of Vinp−Vinn in a binary search such as the binary search illustrated by the decision tree diagram 420 in FIG. 4.

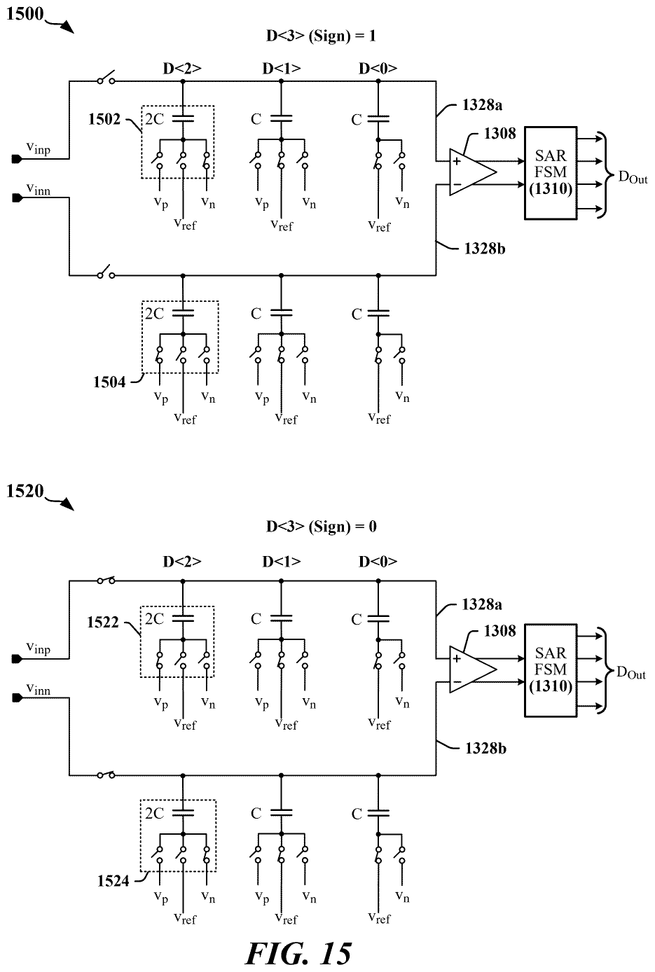

FIGS. 15-18 illustrate examples of configurations of the SAR ADC 1300 that may be used during the conversion phase. A first configuration 1500 shown in FIG. 15 may be used when the initial comparison of Vᵢₙₚ and Vᵢₙₙ results in D<3>=1. In this configuration 1500, the first input 1328a of the comparator 1308 is coupled to the vₙ reference voltage through a first capacitor configuration 1502 associated with the D<2> bit segment 1304a, and the second input 1328b of the comparator 1308 is coupled to the vₚ reference voltage through a second capacitor configuration 1504 associated with the D<2> bit segment 1306a. In this configuration 1500, the voltage Vᵢₙₚ(t₁) at the first input 1328a of the comparator 1308 may be calculated as:

$$\begin{matrix}{V}_{inp} ( {t}_{1} ) = {V}_{inp} ( {t}_{0} ) - ( {v}_{ref} \frac{2 C}{8 C} ) \\ = {V}_{inp} ( {t}_{0} ) - \frac{1}{4} {v}_{ref}\end{matrix} ,$$

where Vᵢₙₚ(t₀) is the voltage at the first input 1328a of the comparator 1308 during sign determination (i.e., D<3>). In this configuration 1500, the voltage Vᵢₙₙ(t₁) at the second input 1328b of the comparator 1308 may be calculated as:

$$\begin{matrix}{V}_{inn} ( {t}_{1} ) = {V}_{inn} ( {t}_{0} ) + ( {v}_{ref} \frac{2 C}{8 C} ) \\ = {V}_{inn} ( {t}_{0} ) + \frac{1}{4} {v}_{ref}\end{matrix} ,$$

where Vᵢₙₙ(t₀) is the voltage at the second input 1328b of the comparator 1308 during sign determination (i.e., D<3>). In this configuration 1500, the voltage difference between the inputs 1328a and 1328b of the comparator 1308 may be calculated as:

$${V}_{inp} ( {t}_{1} ) - {V}_{inn} ( {t}_{1} ) = {V}_{inp} ( {t}_{0} ) - {V}_{inn} ( {t}_{0} ) - \frac{1}{2} {v}_{ref} .$$

A second configuration 1520 shown in FIG. 15 may be used when D<3>=0. In this configuration 1520, the first input 1328a of the comparator 1308 is coupled to the vₚ reference voltage through a first capacitor configuration 1522 associated with the D<2> bit segment 1304a, and the second input 1328b of the comparator 1308 is coupled to the vₙ reference voltage through a second capacitor configuration 1524 associated with the D<2> bit segment 1306a. In this configuration 1520, the voltage Vᵢₙₚ(t₁) at the first input 1328a of the comparator 1308 may be calculated as:

$$\begin{matrix}{V}_{inp} ( {t}_{1} ) = {V}_{inp} ( {t}_{0} ) + ( {v}_{ref} \frac{2 C}{8 C} ) \\ = {V}_{inp} ( {t}_{0} ) + \frac{1}{4} {v}_{ref}\end{matrix} .$$

In this configuration 1520, the voltage Vᵢₙₙ(t₁) at the second input 1328b of the comparator 1308 may be calculated as:

$$\begin{matrix}{V}_{inn} ( {t}_{1} ) = {V}_{inn} ( {t}_{0} ) - ( {v}_{ref} \frac{2 C}{8 C} ) \\ = {V}_{inn} ( {t}_{0} ) - \frac{1}{4} {v}_{ref}\end{matrix} .$$

In this configuration 1520, the voltage difference between the inputs 1328a and 1328b of the comparator 1308 may be calculated as:

$${V}_{inp} ( {t}_{1} ) - {V}_{inn} ( {t}_{1} ) = {V}_{inp} ( {t}_{0} ) - {V}_{inn} ( {t}_{0} ) + \frac{1}{2} {v}_{ref} .$$

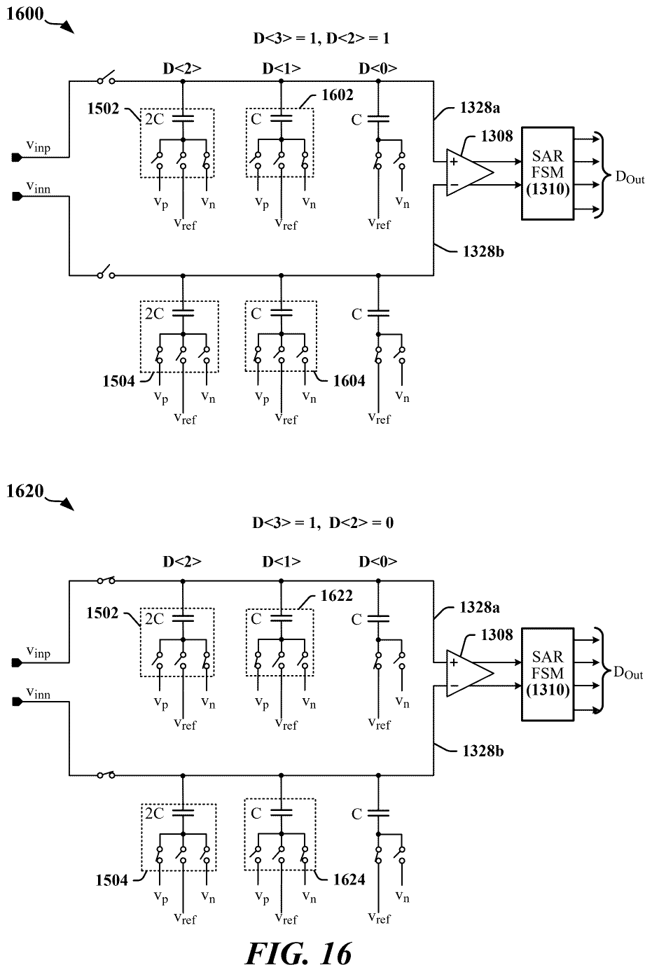

A first configuration 1600 shown in FIG. 16 may be used when D<3>=1 and D<2>=1. In this configuration 1600, the first input 1328a of the comparator 1308 remains coupled to the vₙ reference voltage through the first capacitor configuration 1502 associated with the D<2> bit segment 1304a, and the second input 1328b of the comparator 1308 remains coupled to the vₚ reference voltage through the second capacitor configuration 1504 associated with the D<2> bit segment 1306a. The first input 1328a of the comparator 1308 is also coupled to the vₙ reference voltage through the first capacitor configuration 1602 associated with the D<1> bit segment 1304b, and the second input 1328b of the comparator 1308 is also coupled to the vₚ reference voltage through the second capacitor configuration 1604 associated with the D<1> bit segment 1306b. In this configuration 1600, the voltage Vᵢₙₚ(t₂) at the first input 1328a of the comparator 1308 may be calculated as:

$$\begin{matrix}{V}_{inp} ( {t}_{2} ) = {V}_{inp} ( {t}_{0} ) - ( {v}_{ref} \frac{2 C}{8 C} ) - ( {v}_{ref} \frac{C}{8 C} ) \\ = {V}_{inp} ( {t}_{0} ) - \frac{3}{8} {V}_{ref}\end{matrix} .$$

In this configuration 1600, the voltage Vᵢₙₙ(t₂) at the second input 1328b of the comparator 1308 may be calculated as:

$$\begin{matrix}{V}_{inn} ( {t}_{2} ) = {V}_{inn} ( {t}_{0} ) + ( {v}_{ref} \frac{2 C}{8 C} ) + ( {v}_{ref} \frac{C}{8 C} ) \\ = {V}_{inn} ( {t}_{0} ) + \frac{3}{8} {v}_{ref}\end{matrix} .$$

In this configuration 1600, the voltage difference between the inputs 1328a and 1328b of the comparator 1308 may be calculated as:

$${V}_{inp} ( {t}_{2} ) - {V}_{inn} ( {t}_{2} ) = {V}_{inp} ( {t}_{0} ) - {V}_{inn} ( {t}_{0} ) - \frac{3}{4} {v}_{ref} .$$

A second configuration 1620 shown in FIG. 16 may be used when D<3>=1 and D<2>=0. In this configuration 1620, the first input 1328a of the comparator 1308 remains coupled to the vₙ reference voltage through the first capacitor configuration 1502 associated with the D<2> bit segment 1304a, and the second input 1328b of the comparator 1308 remains coupled to the vₚ reference voltage through the second capacitor configuration 1504 associated with the D<2> bit segment 1306a. The first input 1328a of the comparator 1308 is coupled to the vₚ reference voltage through the first capacitor configuration 1622 associated with the D<1> bit segment 1304b, and the second input 1328b of the comparator 1308 is coupled to the vₙ reference voltage through the second capacitor configuration 1624 associated with the D<1> bit segment 1306b. In this configuration 1620, the voltage Vᵢₙₚ(t₂) at the first input 1328a of the comparator 1308 may be calculated as:

$$\begin{matrix}{V}_{inp} ( {t}_{2} ) = {V}_{inp} ( {t}_{0} ) - ( {v}_{ref} \frac{2 C}{8 C} ) + ( {v}_{ref} \frac{C}{8 C} ) \\ = {V}_{inp} ( {t}_{0} ) - \frac{1}{8} {V}_{ref}\end{matrix} .$$

In this configuration 1620, the voltage Vᵢₙₙ(t₂) at the second input 1328b of the comparator 1308 may be calculated as:

$$\begin{matrix}{V}_{inn} ( {t}_{2} ) = {V}_{inn} ( {t}_{0} ) + ( {v}_{ref} \frac{2 C}{8 C} ) - ( {v}_{ref} \frac{C}{8 C} ) \\ = {V}_{inp} ( {t}_{0} ) + \frac{1}{8} {v}_{ref}\end{matrix} .$$

In this configuration 1620, the voltage difference between the inputs 1328a and 1328b of the comparator 1308 may be calculated as:

$${V}_{inp} ( {t}_{2} ) - {V}_{inn} ( {t}_{2} ) = {V}_{inp} ( {t}_{0} ) - {V}_{inn} ( {t}_{0} ) - \frac{1}{4} {v}_{ref} .$$

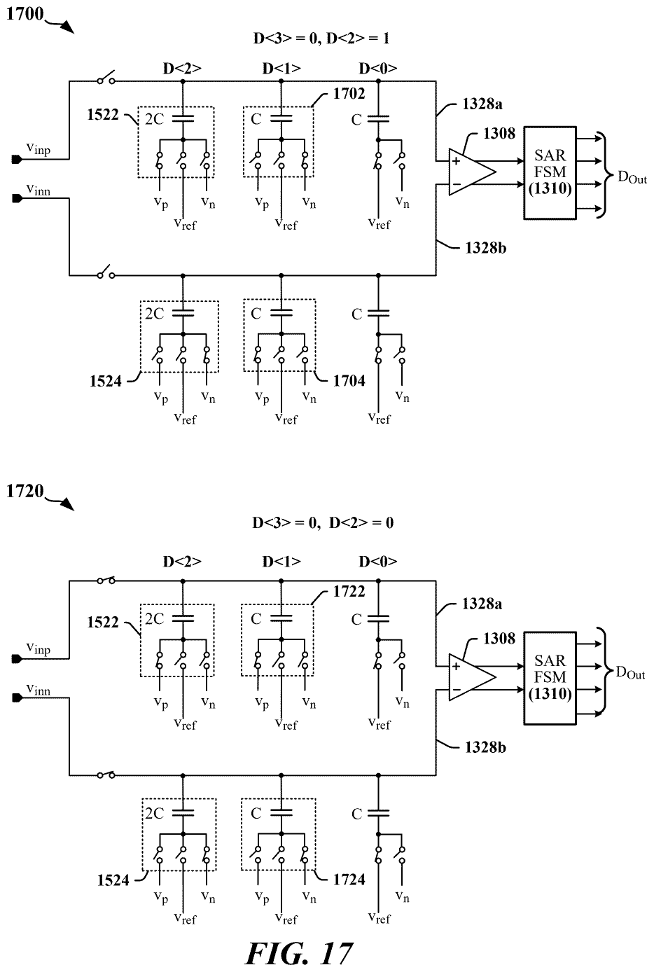

A first configuration 1700 shown in FIG. 17 may be used when D<3>=0 and D<2>=1. In this configuration 1700, the first input 1328a of the comparator 1308 is coupled to the vₚ reference voltage through the first capacitor configuration 1522 associated with the D<2> bit segment 1304a, and the second input 1328b of the comparator 1308 is coupled to the vₙ reference voltage through the second capacitor configuration 1524 associated with the D<2> bit segment 1306a. The first input 1328a of the comparator 1308 is coupled to the vₙ reference voltage through the first capacitor configuration 1702 associated with the D<1> bit segment 1304b, and the second input 1328b of the comparator 1308 is coupled to the vₚ reference voltage through the second capacitor configuration 1704 associated with the D<1> bit segment 1306b. In this configuration 1700, the voltage Vᵢₙₚ(t₂) at the first input 1328a of the comparator 1308 may be calculated as:

$$\begin{matrix}{V}_{inp} ( {t}_{2} ) = {V}_{inp} ( {t}_{0} ) + ( {v}_{ref} \frac{2 C}{8 C} ) - ( {v}_{ref} \frac{C}{8 C} ) \\ = {V}_{inp} ( {t}_{0} ) + \frac{1}{8} {v}_{ref} .\end{matrix}$$

In this configuration 1700, the voltage Vᵢₙₙ(t₂) at the second input 1328b of the comparator 1308 may be calculated as:

$$\begin{matrix}{V}_{inn} ( {t}_{2} ) = {V}_{inn} ( {t}_{0} ) - ( {v}_{ref} \frac{2 C}{8 C} ) + ( {v}_{ref} \frac{C}{8 C} ) \\ = {V}_{inn} ( {t}_{0} ) - \frac{1}{8} {v}_{ref} .\end{matrix}$$

In this configuration 1700, the voltage difference between the inputs 1328a and 1328b of the comparator 1308 may be calculated as:

$${V}_{inp} ( {t}_{2} ) - {V}_{inn} ( {t}_{2} ) = {V}_{inp} ( {t}_{0} ) - {V}_{inn} ( {t}_{0} ) + \frac{1}{4} {v}_{ref} .$$

A second configuration 1720 shown in FIG. 17 may be used when D<3>=0 and D<2>=0. In this configuration 1720, the first input 1328a of the comparator 1308 is coupled to the vₚ reference voltage through the first capacitor configuration 1522 associated with the D<2> bit segment 1304a, and the second input 1328b of the comparator 1308 is coupled to the vₙ reference voltage through the second capacitor configuration 1524 associated with the D<2> bit segment 1306a. The first input 1328a of the comparator 1308 is coupled to the vₚ reference voltage through the first capacitor configuration 1722 associated with the D<1> bit segment 1304b, and the second input 1328b of the comparator 1308 is coupled to the vₙ reference voltage through the second capacitor configuration 1724 associated with the D<1> bit segment 1306b. In this configuration 1720, the voltage Vᵢₙₚ(t₂) at the first input 1328a of the comparator 1308 may be calculated as:

$$\begin{matrix}{V}_{inp} ( {t}_{2} ) = {V}_{inp} ( {t}_{0} ) + ( {v}_{ref} \frac{2 C}{8 C} ) + ( {v}_{ref} \frac{C}{8 C} ) \\ = {V}_{inp} ( {t}_{0} ) + \frac{3}{8} {v}_{ref} .\end{matrix}$$

In this configuration 1720, the voltage Vᵢₙₙ(t₂) at the second input 1328b of the comparator 1308 may be calculated as:

$$\begin{matrix}{V}_{inn} ( {t}_{2} ) = {V}_{inn} ( {t}_{0} ) - ( {v}_{ref} \frac{2 C}{8 C} ) + ( {v}_{ref} \frac{C}{8 C} ) \\ = {V}_{inn} ( {t}_{0} ) - \frac{3}{8} {v}_{ref} .\end{matrix}$$

In this configuration 1720, the voltage difference between the inputs 1328a and 1328b of the comparator 1308 may be calculated as:

$${V}_{inp} ( {t}_{2} ) - {V}_{inn} ( {t}_{2} ) = {V}_{inp} ( {t}_{0} ) - {V}_{inn} ( {t}_{0} ) + \frac{3}{4} {v}_{ref} .$$

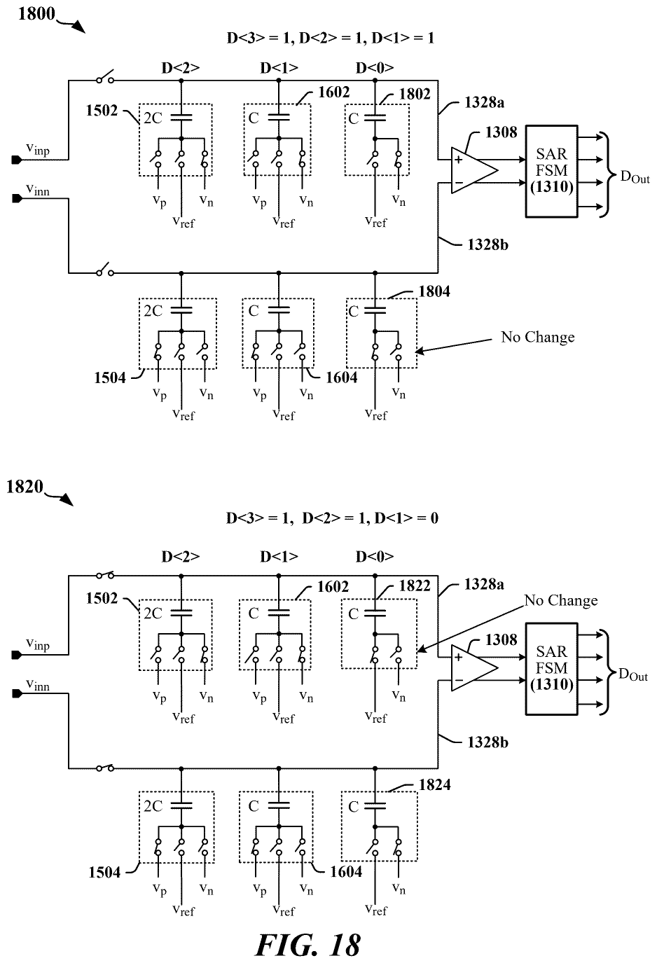

A first configuration 1800 shown in FIG. 18 may be used when D<3>=1, D<2>=1 and D<1>=1. In this configuration 1800, the first input 1328a of the comparator 1308 remains coupled to the vₙ reference voltage through the first capacitor configuration 1502 associated with the D<2> bit segment 1304a and the first capacitor configuration 1602 associated with the D<1> bit segment 1304b (see FIGS. 13-16). The second input 1328b of the comparator 1308 remains coupled to the vₚ reference voltage through the second capacitor configuration 1504 associated with the D<2> bit segment 1306a and the second capacitor configuration 1604 associated with the D<1> bit segment 1306b. The first input 1328a of the comparator 1308 is also coupled to the vₙ reference voltage through the first capacitor configuration 1802 associated with the D<0> bit segment 1304c. The second capacitor configuration 1804 associated with the D<0> bit segment 1306c remains unchanged from the previous bit resolution cycle as represented by the first configuration 1600 shown in FIG. 16. In configuration 1800, the voltage Vᵢₙₚ(t₃) at the first input 1328a of the comparator 1308 may be calculated as:

$$\begin{matrix}{V}_{inp} ( {t}_{3} ) = {V}_{inp} ( {t}_{0} ) - ( {v}_{ref} \frac{2 C}{8 C} ) - ( {v}_{ref} \frac{C}{8 C} ) - ( {v}_{ref} \frac{C}{8 C} ) \\ = {V}_{inp} ( {t}_{0} ) - \frac{4}{8} {v}_{ref} .\end{matrix}$$

In this configuration 1800, the voltage Vᵢₙₙ(t₃) at the second input 1328b of the comparator 1308 may be calculated as:

$$\begin{matrix}{V}_{inn} ( {t}_{3} ) = {V}_{inn} ( {t}_{0} ) + ( {v}_{ref} \frac{2 C}{8 C} ) + ( {v}_{ref} \frac{C}{8 C} ) \\ = {V}_{inn} ( {t}_{0} ) + \frac{3}{8} {v}_{ref} .\end{matrix}$$

In this configuration 1800, the voltage difference between the inputs 1328a and 1328b of the comparator 1308 may be calculated as:

$${V}_{inp} ( {t}_{3} ) - {V}_{inn} ( {t}_{3} ) = {V}_{inp} ( {t}_{0} ) - {V}_{inn} ( {t}_{0} ) - \frac{7}{8} {v}_{ref} .$$

A second configuration 1820 shown in FIG. 18 may be used when D<3>=1, D<2>=1 and D<1>=0. In this configuration 1820, the first input 1328a of the comparator 1308 remains coupled to the vₙ reference voltage through the first capacitor configuration 1502 associated with the D<2> bit segment 1304a, and through the first capacitor configuration 1602 associated with the D<1> bit segment 1304b. The second input 1328b of the comparator 1308 remains coupled to the vₚ reference voltage through the second capacitor configuration 1504 associated with the D<2> bit segment 1306a, and through the second capacitor configuration 1604 associated with the D<1> bit segment 1306b. The first capacitor configuration 1822 associated with the D<0> bit segment 1304c remains unchanged from the previous bit resolution cycle as represented by the first configuration 1600 shown in FIG. 16. The second input 1328b of the comparator 1308 is coupled to the vₙ reference voltage through the second capacitor configuration 1824 associated with the D<0> bit segment 1306c. In this configuration 1820, the voltage Vᵢₙₚ(t₃) at the first input 1328a of the comparator 1308 may be calculated as:

$$\begin{matrix}{V}_{inp} ( {t}_{3} ) = {V}_{inp} ( {t}_{0} ) - ( {v}_{ref} \frac{2 C}{8 C} ) - ( {v}_{ref} \frac{C}{8 C} ) \\ = {V}_{inp} ( {t}_{0} ) - \frac{3}{8} {v}_{ref} .\end{matrix}$$

In this configuration 1820, the voltage Vᵢₙₙ(t₃) at the second input 1328b of the comparator 1308 may be calculated as:

$$\begin{matrix}{V}_{inn} ( {t}_{3} ) = {V}_{inn} ( {t}_{0} ) + ( {v}_{ref} \frac{2 C}{8 C} ) + ( {v}_{ref} \frac{C}{8 C} ) \\ = {V}_{inn} ( {t}_{0} ) + \frac{2}{8} {v}_{ref} .\end{matrix}$$

In this configuration 1820, the voltage difference between the inputs 1328a and 1328b of the comparator 1308 may be calculated as:

$${V}_{inp} ( {t}_{3} ) - {V}_{inn} ( {t}_{3} ) = {V}_{inp} ( {t}_{0} ) - {V}_{inn} ( {t}_{0} ) - \frac{5}{8} {v}_{ref} .$$

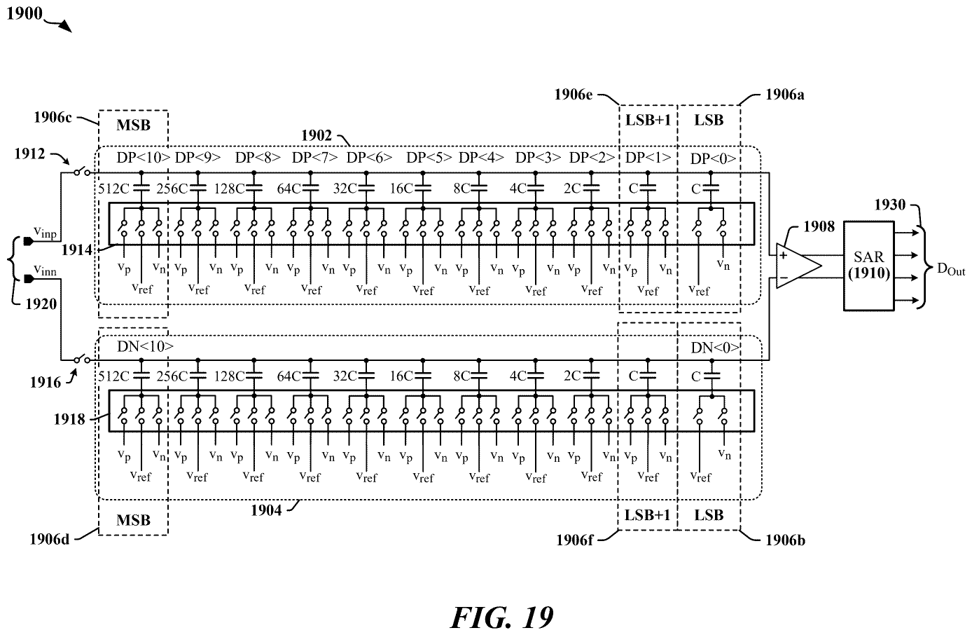

FIG. 19 illustrates a second example of SAR ADC 1900 that can implement a hybrid capacitance switching scheme in accordance with certain aspects of this disclosure. The SAR ADC 1900 corresponds in some respects to the SAR ADC 1300 illustrated in FIG. 13. For example, the SAR ADC 1900 may be considered to be a version of the SAR ADC 1300 that provides increased bit resolution in a digital representation of the amplitude of an analog signal. The illustrated SAR ADC 1900 may be configured to encode a 12-bit digital representation of the amplitude of a differential input signal 1920 in a digital output signal 1930. In some implementations, the 12-bit digital representation of the amplitude of a differential input signal 1920 includes a sign bit.

The SAR ADC 1900 is implemented using capacitive DACs 1902, 1904 configured to receive the differential input signal 1920 through input switches 1912, 1916. The illustrated SAR ADC 1900 includes a first capacitive DAC 1902, a second capacitive DAC 1904, and a comparator 1908, a SAR 1910. The SAR 1910 may include or cooperate with a finite state machine (FSM), a processor, sequencing logic and/or other logic circuits. The first capacitive DAC 1902 includes eleven binary-weighted bit segments (DP<0>-DP<10>). The second capacitive DAC 1904 includes eleven binary-weighted bit segments (DN<0>-DN<10>). According to one aspect, the capacitive DACs 1902, 1904 do not include or require a dummy bit segment. Each of the bit segments includes a single switched capacitor. The capacitances of the switched capacitors are configured to define binary weights provided by the bit segments.

In the illustrated example, the LSB bit segments 1906a, 1906b may be assigned a binary weight of 1 and each of these LSB bit segments 1906a, 1906b includes a switched capacitor that provides a smallest capacitance (C), which may be referred to as the unit capacitance. Successive bit segments may be assigned a binary weight that doubles for each bit segment using capacitors to provide a capacitance that doubles for each successive bit position. In the illustrated example, the most significant bit (MSB) bit segments 1906c, 1906d may be assigned a binary weight of 1024 and each of these MSB bit segments 1906c, 1906d includes a capacitor that provides a capacitance that is 512 times greater than the unit capacitance.

In the illustrated SAR ADC 1900, the first capacitive DAC 1902 includes a first switching circuit 1914 that includes switches that are coupled to a first terminal of the capacitors in the first capacitive DAC 1902. The second capacitive DAC 1904 includes a second switching circuit 1918 that includes switches that are coupled to the first terminal of the capacitors in the second capacitive DAC 1904. For all but the LSB bit segments 1906a and 1906b, switches in the switching circuits 1914, 1918 enable the first terminal of each capacitor to be selectively coupled to a positive voltage (vₚ), a negative voltage (vₙ), or a common-mode reference voltage (v_{ref}). Switches in the switching circuits 1914, 1918 enable the first terminal of each capacitor in the LSB bit segments 1906a and 1906b to be selectively coupled to one of vₚ, vₙ Or v_{ref}. In certain implementations, the voltage level of the common-mode reference voltage may be defined or calculated as v_{cm_ref}=(vₚ+vₙ)/2. In some implementations, the designated reference voltage may be provided at circuit ground or another voltage level.

The SAR ADC 1900 can be configured to convert the voltage difference between a first analog input signal (Vᵢₙₚ) and second analog input signal (Vᵢₙₙ) in an analog-to-digital conversion operation that includes a sampling phase and a conversion phase. In one aspect of this disclosure, the sampling and conversion phases can be extended versions of the sampling and conversion phases used for the SAR ADC 1300 illustrated in FIG. 13.

The elimination of the dummy segment can reduce the area of semiconductor die required to implement the capacitors in the capacitive DACs 1902, 1904. In some implementations, a unit capacitance is provided in the LSB bit segments 1906a and 1906b. Unit capacitance is also provided in the LSB+1 bit segments 1906e and 1906f, enabling a 50% reduction in required area of semiconductor die. In some implementations, the switches used to couple the capacitors in the LSB bit segments 1906a and 1906b to reference voltages may be controlled using encoded single-bit binary numbers. In certain implementations, the switches used to couple the capacitors in the LSB+1 bit segments 1906e and 1906f to reference voltages may be controlled using ternary numbers. The combination of ternary and binary control of the switching circuits 1914, 1918 may be referred to as hybrid switching.

The combined reduction in required area of a semiconductor die for capacitors that is achieved through the use of hybrid capacitance switching and the provision of unit capacitance in both the LSB bit segments 1906a, 1906b and the LSB+1 bit segments 1906e, 1906f can amount to 75% with respect to certain conventional SAR ADCs. In one example, the illustrated SAR ADC 1900 can provide 12-bit resolution using hybrid switching using 2048×unit capacitance, whereas a conventional SAR ADC of comparable resolution requires 8192×unit capacitance.

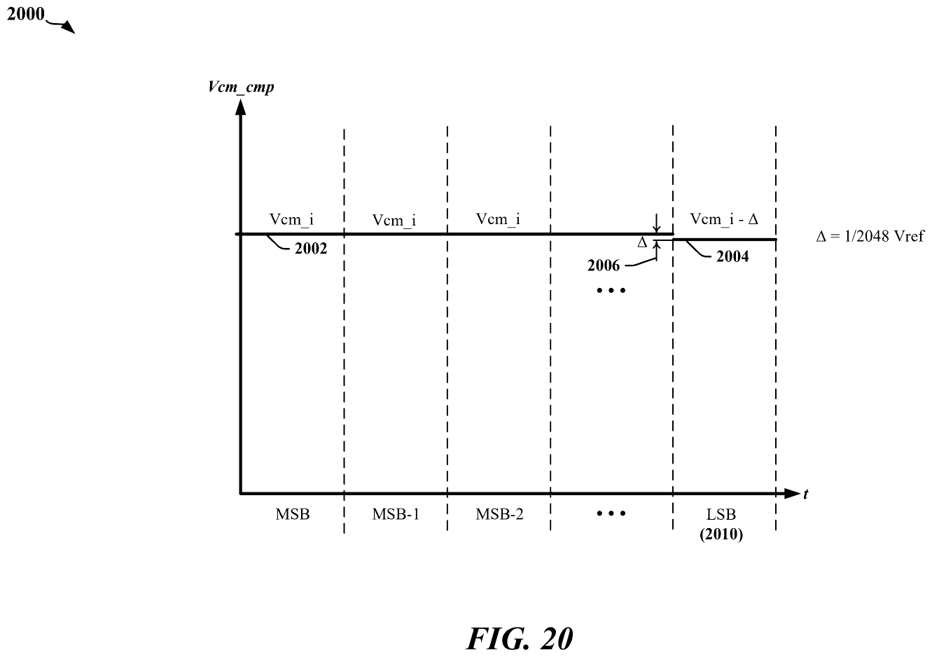

FIG. 20 includes a graph 2000 that shows an example of common mode voltage at the input of the comparator 1908 shown in FIG. 19. In this example, a hybrid switching scheme is employed whereby all bit segments except the LSB bit segments 1906a, 1906b are controlled using complementary capacitance switching while the LSB bit segments 1906a, 1906b are controlled using single-sided capacitance switching. It can be expected the expected the common mode voltage remains at a substantially constant voltage level for all bit segments except when using the LSB bit segments 1906a, 1906b to resolve LSB 2010. In the illustrated example, the common mode voltage remains at a voltage level 2002 (v_{cm_i}) when resolving all but the LSB 2010. The difference 2006 (Δ) between v_{em_i} and the common mode voltage 2004 at the input of the comparator 1908 when resolving LSB 2010 may be calculated for an SAR ADC as:

$$Δ = {( \frac{1}{2} )}^{n} \times {v}_{ref} ,$$

where n is the bit resolution of the SAR ADC, without the sign bit. In the example illustrated in FIG. 19, where n=11, and taking, v_{ref}=1 then:

$$Δ = {( \frac{1}{2} )}^{11} \times 1 V = \frac{1 V}{2048} \approx 0.5 mV .$$

In certain implementations, the v_{ref} reference voltage is provided by a buffer. Noise introduced by the buffer is received at both capacitive DACs 1902, 1904 and presents at the comparator 1908 as common mode noise. The comparator 1908 can be expected to cancel or attenuate the common mode noise so severely as to render it negligible.

The use of ternary CDACs provides symmetry using single capacitors in each bit segment. The ability to operate symmetrically with single capacitors saves 50% of the area of semiconductor die required to implement the capacitors in conventional capacitive DACs. The elimination of the dummy bit segment and the use of single-sided switching (i.e., only one of vₚ Or vₙ is used) in the LSB bit segments 1906a, 1906b enables the use of unit capacitance in both the LSB bit segments 1906a, 1906b and the LSB+1 bit segments 1906e and 1906f. Accordingly, the capacitance used in the MSB bit segments 1906c, 1906d can be limited to 512×unit capacitance rather than 1024×unit capacitance, thereby further halving the area of semiconductor die required to implement the capacitors in conventional capacitive DACs.

The reduction in physical size of capacitance components in the capacitive DACs 1902, 1904 can reduce design complexity and power consumption of audio front end buffers and reference voltage buffer by reducing driving capability requirements. The resultant SAR ADC 1900 can operate at the same full scale input range as conventional SAR ADCs

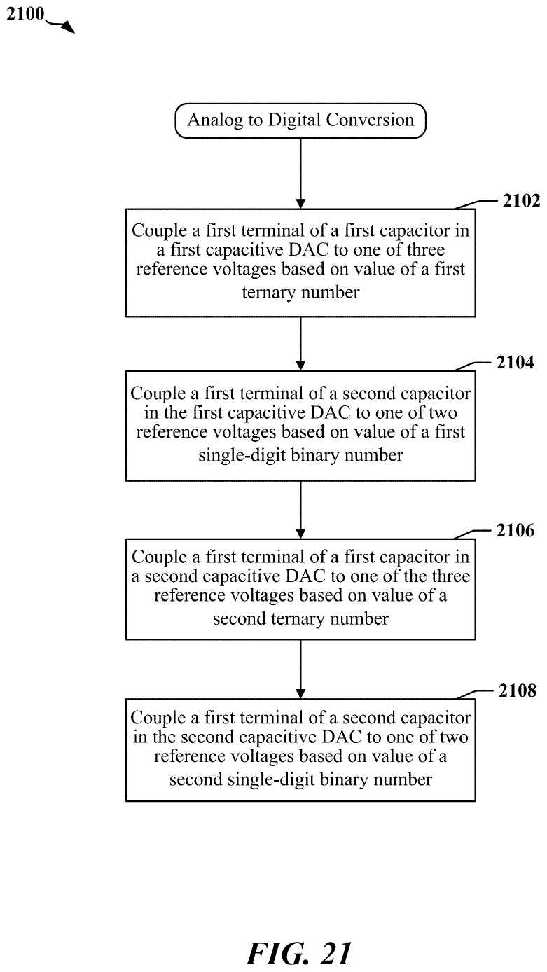

FIG. 21 is a flow diagram illustrating an example of a method 2100 for performing analog-to-digital conversion in accordance with certain aspects of the present disclosure. The method may be performed using the SAR ADC 1300 illustrated in FIG. 13 or the SAR ADC 1900 illustrated in FIG. 19.

At block 2102, a first terminal of a first capacitor in a first capacitive DAC may be coupled to one of three reference voltages based on value of a first ternary number. At block 2104, a first terminal of a second capacitor in the first capacitive DAC may be coupled to one of two reference voltages based on value of a first single-digit binary number. At block 2106, a first terminal of a first capacitor in a second capacitive DAC may be coupled to one of the three reference voltages based on value of a second ternary number. At block 2108, a first terminal of a second capacitor in the second capacitive DAC may be coupled to one of two reference voltages based on value of a second single-digit binary number.

In some implementations, the three reference voltages include a common-mode reference voltage. The common-mode reference voltage may be coupled to each capacitor in each capacitive DAC when an input to the analog-to-digital converter is being sampled.

In certain implementations, the first capacitor in the first capacitive DAC is one of a plurality of capacitors in the first capacitive DAC that provide different binary-weighted capacitances. The first capacitor in the first capacitive DAC may provide a capacitance that is nominally the same as the capacitance provided by the first capacitor in the second capacitive DAC. The first capacitor in the second capacitive DAC may be one of a plurality of capacitors in the second capacitive DAC that provide different binary-weighted capacitances.

In certain implementations, a second terminal of the first capacitor in the first capacitive DAC and a second terminal of the second capacitor in the first capacitive DAC are coupled to a first input of a comparator. A second terminal of the first capacitor in the second capacitive DAC and a second terminal of the second capacitor in the second capacitive DAC may be coupled to a second input of the comparator. A code representative of a voltage difference between outputs of the first capacitive DAC and the second capacitive DAC may be generated.

The operational steps described in any of the exemplary aspects herein are described to provide examples. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering. In certain aspects, an apparatus includes means for coupling a first terminal of a first capacitor in a first capacitive DAC to one of three reference voltages based on a value of a first ternary number, means for coupling a first terminal of a second capacitor in the first capacitive DAC to one of the three reference voltages selected by a value of a first single-digit binary number, means for coupling a first terminal of a first capacitor in a second capacitive DAC to one of the three reference voltages based on a value of a second ternary number, and means for coupling a first terminal of a second capacitor in the second capacitive DAC to one of the three reference voltages selected by a value of a second single-digit binary number.

In some implementations, the three reference voltages include a common-mode reference voltage. The common-mode reference voltage may be coupled to each capacitor in each capacitive DAC when an input to the analog-to-digital converter is being sampled.

In certain implementations, the first capacitor in the first capacitive DAC is one of a plurality of capacitors in the first capacitive DAC that provide different binary-weighted capacitances. The first capacitor in the first capacitive DAC may provide a capacitance that is nominally the same as the capacitance provided by the first capacitor in the second capacitive DAC. The first capacitor in the second capacitive DAC may be one of a plurality of capacitors in the second capacitive DAC that provide different binary-weighted capacitances.

In certain implementations, the apparatus has means for determining a voltage difference between outputs of the first capacitive DAC and the second capacitive DAC. The means for determining the voltage difference may include a comparator. The comparator may have a first input coupled to a second terminal of the first capacitor in the first capacitive DAC and to a second terminal of the second capacitor in the first capacitive DAC. The comparator may have a second input coupled to a second terminal of the first capacitor in the second capacitive DAC and to a second terminal of the second capacitor in the second capacitive DAC are coupled to a second input of the comparator.

In accordance with certain aspects of this disclosure, an ADC includes a first capacitor in a first DAC, first switches configured to selectively couple the first terminal of the first capacitor in the first capacitive DAC to one of three reference voltages, a second capacitor in the first capacitive DAC, second switches configured to switch the first terminal of the second capacitor in the first capacitive DAC between two of the three reference voltages, a first capacitor in a second capacitive DAC, third switches configured to selectively couple the first terminal of the first capacitor in the second capacitive DAC to one of the three reference voltages, a second capacitor in the second capacitive DAC, and fourth switches configured to switch the first terminal of the second capacitor in the second capacitive DAC between two of the three reference voltages. The first switches and the third switches may be controlled based on a value of a ternary number. The second switches and the fourth switches may be controlled based on a value of a single-digit binary number.

In certain implementations, the three reference voltages include a common-mode reference voltage. The common-mode reference voltage may be coupled to each capacitor in each capacitive DAC when an input to the analog-to-digital converter is being sampled.

In certain implementations, the first capacitor in the first capacitive DAC provides a capacitance that is larger than the capacitance provided by the second capacitor in the first capacitive DAC by factor of 2″ where n is a non-negative integer. The first capacitor in the first capacitive DAC may be one of a plurality of capacitors in the first capacitive DAC that provide different binary-weighted capacitances. The first capacitor in the first capacitive DAC may provide a capacitance that is nominally the same as the capacitance provided by the first capacitor in the second capacitive DAC. The first capacitor in the second capacitive DAC may be one of a plurality of capacitors in the second capacitive DAC that provide different binary-weighted capacitances.

In certain implementations, a comparator may be configured to generate a code representative of a voltage difference between outputs of the first capacitive DAC and the second capacitive DAC. A second terminal of the first capacitor in the first capacitive DAC and a second terminal of the second capacitor in the first capacitive DAC may be coupled to a first input of the comparator. A second terminal of the first capacitor in the second capacitive DAC and a second terminal of the second capacitor in the second capacitive DAC may be coupled to a second input of the comparator.

Some implementation examples are described in the following numbered clauses:
1. An analog-to-digital converter, comprising: a first capacitor in a first capacitive digital-to-analog converter (DAC); first switches configured to selectively couple a first terminal of the first capacitor in the first capacitive DAC to one of three voltages; a second capacitor in the first capacitive DAC; second switches configured to switch a first terminal of the second capacitor in the first capacitive DAC between two of the three voltages; a first capacitor in a second capacitive DAC; third switches configured to selectively couple a first terminal of the first capacitor in the second capacitive DAC to one of the three voltages; a second capacitor in the second capacitive DAC; and fourth switches configured to switch a first terminal of the second capacitor in the second capacitive DAC between two of the three voltages, wherein the first switches and the third switches are controlled based on a value of a ternary number, and wherein the second switches and the fourth switches are controlled based on a value of a single-digit binary number.
2. The analog-to-digital converter as described in clause 1, wherein the three voltages include a reference voltage.
3. The analog-to-digital converter as described in clause 2, wherein the reference voltage is coupled to each capacitor in each capacitive DAC when an input to the analog-to-digital converter is being sampled.
4. The analog-to-digital converter as described in any of clauses 1-3, wherein the first capacitor in the first capacitive DAC provides a capacitance that is larger than the capacitance provided by the second capacitor in the first capacitive DAC by factor of 2ⁿ where n is a non-negative integer.
5. The analog-to-digital converter as described in any of clauses 1-4, wherein the first capacitor in the first capacitive DAC is one of a plurality of capacitors in the first capacitive DAC that provide different binary-weighted capacitances.
6. The analog-to-digital converter as described in clause 5, wherein the first capacitor in the first capacitive DAC provides a capacitance that is nominally the same as the capacitance provided by the first capacitor in the second capacitive DAC, and wherein the first capacitor in the second capacitive DAC is one of a plurality of capacitors in the second capacitive DAC that provide different binary-weighted capacitances.
7. The analog-to-digital converter as described in any of clauses 1-6, further comprising: a comparator configured to generate a code representative of a voltage difference between outputs of the first capacitive DAC and the second capacitive DAC.
8. The analog-to-digital converter as described in clause 7, wherein a second terminal of the first capacitor in the first capacitive DAC and a second terminal of the second capacitor in the first capacitive DAC are coupled to a first input of the comparator, and wherein a second terminal of the first capacitor in the second capacitive DAC and a second terminal of the second capacitor in the second capacitive DAC are coupled to a second input of the comparator.
9. An apparatus, comprising: means for coupling a first terminal of a first capacitor in a first capacitive digital-to-analog converter (DAC) to one of three voltages based on a value of a first ternary number; means for coupling a first terminal of a second capacitor in the first capacitive DAC to one of the three voltages selected by a value of a first single-digit binary number; means for coupling a first terminal of a first capacitor in a second capacitive DAC to one of the three voltages based on a value of a second ternary number; and means for coupling a first terminal of a second capacitor in the second capacitive DAC to one of the three voltages selected by a value of a second single-digit binary number.
10. The apparatus as described in clause 9, wherein the three voltages include a reference voltage, and wherein the reference voltage is coupled to each capacitor in each capacitive DAC when an input to the apparatus is being sampled.
11. The apparatus as described in clause 10, wherein the first capacitor in the first capacitive DAC is one of a plurality of capacitors in the first capacitive DAC that provide different binary-weighted capacitances.
12. The apparatus as described in clause 11, wherein the first capacitor in the first capacitive DAC provides a capacitance that is nominally the same as the capacitance provided by the first capacitor in the second capacitive DAC, and wherein the first capacitor in the second capacitive DAC is one of a plurality of capacitors in the second capacitive DAC that provide different binary-weighted capacitances.
13. The apparatus as described in any of clauses 9-12, further comprising: means for determining a voltage difference between outputs of the first capacitive DAC and the second capacitive DAC.
14. The apparatus as described in clause 13, wherein the means for determining the voltage difference includes a comparator that has a first input coupled to a second terminal of the first capacitor in the first capacitive DAC and to a second terminal of the second capacitor in the first capacitive DAC, and a second input coupled to a second terminal of the first capacitor in the second capacitive DAC and to a second terminal of the second capacitor in the second capacitive DAC are coupled to a second input of the comparator.
15. A method for performing analog-to-digital conversion, comprising: coupling a first terminal of a first capacitor in a first capacitive digital-to-analog converter (DAC) to one of three voltages based on value of a first ternary number; coupling a first terminal of a second capacitor in the first capacitive DAC to one of two voltages based on value of a first single-digit binary number; coupling a first terminal of a first capacitor in a second capacitive DAC to one of the three voltages based on value of a second ternary number; and coupling a first terminal of a second capacitor in the second capacitive DAC to one of two voltages based on value of a second single-digit binary number.
16. The method as described in clause 15, wherein the three voltages include a reference voltage, and wherein the reference voltage is coupled to each capacitor in each capacitive DAC when an input to an analog-to-digital converter is being sampled.
17. The method as described in clause 15 or clause 16, wherein the first capacitor in the first capacitive DAC is one of a plurality of capacitors in the first capacitive DAC that provide different binary-weighted capacitances.
18. The method as described in clause 17, wherein the first capacitor in the first capacitive DAC provides a capacitance that is nominally the same as the capacitance provided by the first capacitor in the second capacitive DAC, and wherein the first capacitor in the second capacitive DAC is one of a plurality of capacitors in the second capacitive DAC that provide different binary-weighted capacitances.
19. The method as described in any of clauses 15-18, further comprising: generating a code representative of a voltage difference between outputs of the first capacitive DAC and the second capacitive DAC.
20. The method as described in any of clauses 15-19, wherein a second terminal of the first capacitor in the first capacitive DAC and a second terminal of the second capacitor in the first capacitive DAC are coupled to a first input of a comparator, and wherein a second terminal of the first capacitor in the second capacitive DAC and a second terminal of the second capacitor in the second capacitive DAC are coupled to a second input of the comparator.

The present disclosure is provided to enable any person skilled in the art to make or use aspects of the disclosure. Various modifications to the disclosure will be readily apparent to those skilled in the art, and the generic principles defined herein may be applied to other variations without departing from the scope of the disclosure. Thus, the disclosure is not intended to be limited to the examples and designs described herein, but is to be accorded the widest scope consistent with the principles and novel features disclosed herein.

What is claimed is:

1. An analog-to-digital converter, comprising:
a first capacitor in a first capacitive digital-to-analog converter (DAC);
first switches configured to selectively couple a first terminal of the first capacitor in the first capacitive DAC to one of three voltages;
a second capacitor in the first capacitive DAC;
second switches configured to switch a first terminal of the second capacitor in the first capacitive DAC between two of the three voltages;
a first capacitor in a second capacitive DAC;
third switches configured to selectively couple a first terminal of the first capacitor in the second capacitive DAC to one of the three voltages;
a second capacitor in the second capacitive DAC; and
fourth switches configured to switch a first terminal of the second capacitor in the second capacitive DAC between two of the three voltages,
wherein the first switches and the third switches are controlled based on a value of a ternary number, and wherein the second switches and the fourth switches are controlled based on a value of a single-digit binary number.

2. The analog-to-digital converter of claim 1, wherein the three voltages include a reference voltage.

3. The analog-to-digital converter of claim 2, wherein the reference voltage is coupled to each capacitor in each capacitive DAC when an input to the analog-to-digital converter is being sampled.

4. The analog-to-digital converter of claim 1, wherein the first capacitor in the first capacitive DAC provides a capacitance that is larger than the capacitance provided by the second capacitor in the first capacitive DAC by factor of 2″ where n is a non-negative integer.

5. The analog-to-digital converter of claim 1, wherein the first capacitor in the first capacitive DAC is one of a plurality of capacitors in the first capacitive DAC that provide different binary-weighted capacitances.

6. The analog-to-digital converter of claim 5, wherein the first capacitor in the first capacitive DAC provides a capacitance that is nominally the same as the capacitance provided by the first capacitor in the second capacitive DAC, and wherein the first capacitor in the second capacitive DAC is one of a plurality of capacitors in the second capacitive DAC that provide different binary-weighted capacitances.

7. The analog-to-digital converter of claim 1, further comprising:
a comparator configured to generate a code representative of a voltage difference between outputs of the first capacitive DAC and the second capacitive DAC.

8. The analog-to-digital converter of claim 7, wherein a second terminal of the first capacitor in the first capacitive DAC and a second terminal of the second capacitor in the first capacitive DAC are coupled to a first input of the comparator, and wherein a second terminal of the first capacitor in the second capacitive DAC and a second terminal of the second capacitor in the second capacitive DAC are coupled to a second input of the comparator.

9. An apparatus, comprising:
means for coupling a first terminal of a first capacitor in a first capacitive digital-to-analog converter (DAC) to one of three voltages based on a value of a first ternary number;
means for coupling a first terminal of a second capacitor in the first capacitive DAC to one of the three voltages selected by a value of a first single-digit binary number;
means for coupling a first terminal of a first capacitor in a second capacitive DAC to one of the three voltages based on a value of a second ternary number; and
means for coupling a first terminal of a second capacitor in the second capacitive DAC to one of the three voltages selected by a value of a second single-digit binary number.

10. The apparatus of claim 9, wherein the three voltages include a reference voltage, and wherein the reference voltage is coupled to each capacitor in each capacitive DAC when an input to the apparatus is being sampled.

11. The apparatus of claim 10, wherein the first capacitor in the first capacitive DAC is one of a plurality of capacitors in the first capacitive DAC that provide different binary-weighted capacitances.

12. The apparatus of claim 11, wherein the first capacitor in the first capacitive DAC provides a capacitance that is nominally the same as the capacitance provided by the first capacitor in the second capacitive DAC, and wherein the first capacitor in the second capacitive DAC is one of a plurality of capacitors in the second capacitive DAC that provide different binary-weighted capacitances.

13. The apparatus of claim 10, further comprising:
means for determining a voltage difference between outputs of the first capacitive DAC and the second capacitive DAC.

14. The apparatus of claim 13, wherein the means for determining the voltage difference includes a comparator that has a first input coupled to a second terminal of the first capacitor in the first capacitive DAC and to a second terminal of the second capacitor in the first capacitive DAC, and a second input coupled to a second terminal of the first capacitor in the second capacitive DAC and to a second terminal of the second capacitor in the second capacitive DAC are coupled to a second input of the comparator.

15. A method for performing analog-to-digital conversion, comprising:
coupling a first terminal of a first capacitor in a first capacitive digital-to-analog converter (DAC) to one of three voltages based on value of a first ternary number;
coupling a first terminal of a second capacitor in the first capacitive DAC to one of two voltages based on value of a first single-digit binary number;
coupling a first terminal of a first capacitor in a second capacitive DAC to one of the three voltages based on value of a second ternary number; and
coupling a first terminal of a second capacitor in the second capacitive DAC to one of two voltages based on value of a second single-digit binary number.

16. The method of claim 15, wherein the three voltages include a reference voltage, and wherein the reference voltage is coupled to each capacitor in each capacitive DAC when an input to an analog-to-digital converter is being sampled.

17. The method of claim 15, wherein the first capacitor in the first capacitive DAC is one of a plurality of capacitors in the first capacitive DAC that provide different binary-weighted capacitances.

18. The method of claim 17, wherein the first capacitor in the first capacitive DAC provides a capacitance that is nominally the same as the capacitance provided by the first capacitor in the second capacitive DAC, and wherein the first capacitor in the second capacitive DAC is one of a plurality of capacitors in the second capacitive DAC that provide different binary-weighted capacitances.

19. The method of claim 15, further comprising:
generating a code representative of a voltage difference between outputs of the first capacitive DAC and the second capacitive DAC.

20. The method of claim 15, wherein a second terminal of the first capacitor in the first capacitive DAC and a second terminal of the second capacitor in the first capacitive DAC are coupled to a first input of a comparator, and wherein a second terminal of the first capacitor in the second capacitive DAC and a second terminal of the second capacitor in the second capacitive DAC are coupled to a second input of the comparator.
